(19) United States
(12) Patent Application Publication
(10) Pub. No.: US 2012/0061761 A1
(43) Pub. Date: Mar. 15, 2012

(54) SEMICONDUCTOR INTEGRATED CIRCUIT DEVICE AND MANUFACTURING METHOD FOR SEMICONDUCTOR INTEGRATED CIRCUIT DEVICES

(75) Inventors: Hideki MAKIYAMA, Kanagawa (JP); Toshiaki Iwamatsu, Kanagawa (JP)

(73) Assignee: Renesas Electronics Corporation

(21) Appl. No.: 13/186,188

(22) Filed: Jul. 19, 2011

(30) Foreign Application Priority Data
Sep. 9, 2010 (JP) 2010-201974

(51) Int. Cl. H01L 29/78; H01L 27/092; H01L 21/8238

(52) U.S. Cl. 257/355; 438/199; 257/369; 257/E21.632; 257/E27.061; 257/E29.255

(57) ABSTRACT

Logic transistors (MOSFETs, MISFETs) in core portions of integrated circuits can be microminiaturized by scaling operating voltage as their generation advances. However, since transistors (MOSFETs, MISFETs) in high-breakdown voltage portions operate on relatively high power supply voltage, it is difficult to reduce their size. Similarly, electrostatic discharge (ESD) protection circuits in power supply cells protect the elements in a semiconductor integrated circuit against static electricity (foreign surge); therefore, they are indispensably required to be high in breakdown voltage and call for a large area for dissipating electric charges. To microminiaturize integrated circuits, therefore, a transistor structure that enables microminiaturization is indispensable. To solve the above problem, a semiconductor integrated circuit device having in its ESD protection circuit portion a CMIS inverter made up of a pair of MISFETs having a source/drain asymmetric structure and including a halo region only on the source side is provided.

### CROSS-REFERENCE TO RELATED APPLICATIONS

The disclosure of Japanese Patent Application No. 2010-201974 filed on Sep. 9, 2010 including the specification, drawings and abstract is incorporated herein by reference in its entirety.

### BACKGROUND

The present invention relates to a technology effectively applicable to ESD (Electro-Static Discharge) protection technologies for semiconductor integrated circuit devices (or semiconductor devices) or manufacturing methods for semiconductor integrated circuit devices (or semiconductor devices).

U.S. Pat. No. 5,994,176 (Patent Document 1) discloses a technology in which the following measure is taken: a source/drain symmetric FET is used as MISFET (Metal Insulator Semiconductor Field Effect Transistor) for core; and a source/drain asymmetric FET whose drain side is only provided with an LDD (Lightly Doped Drain) structure is used as MISFET for ESD protection circuit.

U.S. Pat. No. 7,393,752 (Patent Document 2) discloses the following source/drain asymmetric FET as a power MOSFET (Metal Oxide Semiconductor Field Effect Transistor) for deep submicron integrated circuit: a source/drain asymmetric FET whose drain side is only provided with an LDD structure and which is provided on the source side with a halo region.

[Patent Document 1]

U.S. Pat. No. 5,994,176

[Patent Document 2]

U.S. Pat. No. 7,393,752

### SUMMARY

Logic transistors (MOSFETs, MOSFETs) in core portions of integrated circuits can be microminiaturized by scaling operating voltage as their generation advances. However, since transistors (MOSFETs, MOSFETs) in high-breakdown voltage portions operate on relatively high power supply voltage, it is difficult to reduce their size. Similarly, electrostatic discharge (ESD) protection circuits in power supply cells protect the elements in a semiconductor integrated circuit against static electricity (foreign surge); therefore, they are indispensably required to be high in breakdown voltage and call for a large area for dissipating electric charges. To microminiaturize integrated circuits, therefore, a transistor structure that enables microminiaturization is indispensable.

The invention has been made to solve these problems.

It is an object of the invention to provide a reliable semiconductor integrated circuit device and a reliable manufacturing process for semiconductor integrated circuit devices.

The above and other objects and novel features of the invention will be apparent from the description in this specification and the accompanying drawings.

The following is a brief description of the gist of the representative elements of the invention laid open in this application:

An aspect of the invention laid open in this application is a semiconductor integrated circuit device having the following CMIS inverter in an ESD protection circuit portion: a CMIS inverter made up of a pair of MISFETs with a source/drain asymmetric structure in which a halo region is provided only on the source side.

The following is a brief description of the gist of the effect obtained by the representative elements of the invention laid open in this application:

A transistor in a high-breakdown voltage portion can be microminiaturized by so configuring a semiconductor integrated circuit device that it has the following CMIS inverter in the ESD protection circuit portion thereof: a CMIS inverter made up of a pair of MISFETs with a source/drain asymmetric structure each having a halo region only on the source side.

### BRIEF DESCRIPTION OF THE DRAWINGS

FIG. 1 is a device sectional view of an n-channel high-breakdown voltage asymmetric MISFET illustrating as an example the basic structure of a high-breakdown voltage asymmetric MISFET in a semiconductor integrated circuit device in an embodiment of the invention laid open in this application;

FIG. 2 is a layout diagram of a chip upper surface and the like explaining a basic configuration, a main device structure, a circuit, and a system over a semiconductor integrated circuit chip related to the semiconductor integrated circuit device in the above embodiment of the invention laid open in this application;

FIG. 3 is a circuit block diagram explaining the relation between a power supply, an ESD protection circuit, an interface portion, a core logic circuit portion, and the like in the layout in FIG. 2;

FIG. 4 is a detailed circuit diagram illustrating a concrete circuit example of the decoupling capacitor portion DC in FIG. 3;

FIG. 5 is a detailed circuit diagram illustrating a concrete circuit example of the ESD protection circuit portion (ESD) in FIG. 3;

FIG. 6 is a detailed circuit diagram illustrating a concrete circuit example of the step-down circuit portion 8 in FIG. 3;

FIG. 7 is a detailed circuit diagram illustrating a concrete circuit example of the signal output buffer circuit portion BF in FIG. 3;

FIG. 8 is a detailed circuit diagram illustrating a concrete circuit example of the high-breakdown voltage symmetric CMISFET-NOR gate (NORS) in FIG. 7;

FIG. 9 is a detailed circuit diagram illustrating a concrete circuit example of the high-breakdown voltage symmetric CMISFET-NAND gate (NANDS) in FIG. 7;

FIG. 10 is a device schematic sectional view schematically illustrating the device structures of the n-channel high-breakdown voltage asymmetric high-Vth MISFET (QNHAH), n-channel high-breakdown voltage asymmetric low-Vth MISFET (QNHAL), p-channel high-breakdown voltage asymmetric high-Vth MISFET (QPHAH), and p-channel high-breakdown voltage asymmetric low-Vth MISFET (QPHAL) in FIG. 5, FIG. 6, and FIG. 7;

FIG. 11 is a device schematic sectional view schematically illustrating the device structures of the n-channel high-breakdown voltage symmetric MISFET (QNHS), p-channel high-breakdown voltage symmetric MISFET (QPHS), and n-channel high-breakdown voltage symmetric MOS capacitors (CHSM1, CHSM2, CHSM3) in FIG. 3, FIG. 4, FIG. 5, FIG. 7, FIG. 8, and FIG. 9;

FIG. 12 is a device schematic sectional view schematically illustrating the device structures of the low-breakdown voltage symmetric MISFETs (QNC, QPC) making up the core logic circuit portion 5 in FIG. 2 and FIG. 3;

FIG. 13 is a device schematic sectional view schematically illustrating the device structures of the ESD protection diodes (D1, D2, D3) in FIG. 3 and FIG. 7;

FIG. 14 is a wafer partial sectional view explaining a main part of a wafer process (basic process) related to a semiconductor integrated circuit device and a manufacturing method therefor in an embodiment of the invention laid open in this specification (element isolation region formation step);

FIG. 15 is a wafer partial sectional view explaining a main part of the wafer process (basic process) related to the semiconductor integrated circuit device and the manufacturing method therefor in the above embodiment of the invention laid open in this specification (step of implanting p-well in low-breakdown voltage core logic circuit portion);

FIG. 16 is a wafer partial sectional view explaining a main part of the wafer process (basic process) related to the semiconductor integrated circuit device and the manufacturing method therefor related to the above embodiment of the invention laid open in this specification (step of implanting p-well in high-breakdown voltage portion);

FIG. 17 is a wafer partial sectional view explaining a main part of the wafer process (basic process) related to the semiconductor integrated circuit device and the manufacturing method therefor in the above embodiment of the invention laid open in this specification (p-type punch through stopper region introduction step);

FIG. 18 is a wafer partial sectional view explaining a main part of the wafer process (basic process) related to the semiconductor integrated circuit device and the manufacturing method therefor in the above embodiment of the invention laid open in this specification (step of forming gate insulating film in high-breakdown voltage portion);

FIG. 19 is a wafer partial sectional view explaining a main part of the wafer process (basic process) related to the semiconductor integrated circuit device and the manufacturing method therefor in the above embodiment of the invention laid open in this specification (step of removing gate insulating film from low-breakdown voltage portion);

FIG. 20 is a wafer partial sectional view explaining a main part of the wafer process (basic process) related to the semiconductor integrated circuit device and the manufacturing method therefor in the above embodiment of the invention laid open in this specification (step of forming gate insulating film in low-breakdown voltage portion);

FIG. 21 is a wafer partial sectional view explaining a main part of the wafer process (basic process) related to the semiconductor integrated circuit device and the manufacturing method therefor in the above embodiment of the invention laid open in this specification (gate electrode film formation step);

FIG. 22 is a wafer partial sectional view explaining a main part of the wafer process (basic process) related to the semiconductor integrated circuit device and the manufacturing method therefor in the above embodiment of the invention laid open in this specification (gate electrode patterning step);

FIG. 23 is a wafer partial sectional view explaining a main part of the wafer process (basic process) related to the semiconductor integrated circuit device and the manufacturing method therefor in the above embodiment of the invention laid open in this specification (symmetric n-type source/drain extension region introduction step);

FIG. 24 is a wafer partial sectional view explaining a main part of the wafer process (basic process) related to the semiconductor integrated circuit device and the manufacturing method therefor in the above embodiment of the invention laid open in this specification (asymmetric n-type drain extension region introduction step);

FIG. 25 is a wafer partial sectional view explaining a main part of the wafer process (basic process) related to the semiconductor integrated circuit device and the manufacturing method therefor in the above embodiment of the invention laid open in this specification (n-type source extension region and p-type halo region introduction step);

FIG. 26 is a wafer partial sectional view explaining a main part of the wafer process (basic process) related to the semiconductor integrated circuit device and the manufacturing method therefor in the above embodiment of the invention laid open in this specification (step of introducing n-type extension region in low-breakdown voltage portion);

FIG. 27 is a wafer partial sectional view explaining a main part of the wafer process (basic process) related to the semiconductor integrated circuit device and the manufacturing method therefor in the above embodiment of the invention laid open in this specification (step of introducing high-concentration n-type source/drain region common to each part);

FIG. 28 is a wafer partial sectional view of a first device modification (punch through stopper omitted structure) corresponding to FIG. 27 (step of introducing high-concentration n-type source/drain region common to each part);

FIG. 29 is a wafer partial sectional view of a first process modification (process in which introduction of punch through stopper & source is common) corresponding to FIG. 25 (step of introducing p-type punch through stopper region, n-type source extension region, and p-type halo region);

FIG. 30 is a wafer partial sectional view of a second process modification (process in which introduction of source/drain in high-breakdown voltage symmetric MISFET is common to drain extension in asymmetric MISFET) corresponding to FIG. 24 (symmetric n-type source/drain extension region and asymmetric n-type drain extension region introduction step);

FIG. 31 is an enlarged sectional view of an n-channel high-breakdown voltage asymmetric MISFET (low-Vth) explaining the details of the punch through stopper introduction step (FIG. 17) in the basic process;

FIG. 32 is an enlarged sectional view of an n-channel high-breakdown voltage asymmetric MISFET (standard-Vth) explaining the details of the punch through stopper introduction step (FIG. 17) in the basic process; and

FIG. 33 is an enlarged sectional view of an n-channel high-breakdown voltage asymmetric MISFET (high-Vth) explaining the details of the punch through stopper introduction step (FIG. 17) in the basic process.

### DETAILED DESCRIPTION

(Overview of Embodiments)

First, description will be given to representative embodiments of the invention laid open in this specification.

1. A semiconductor integrated circuit device includes: (a) a semiconductor chip having a first main surface; (b) a CMIS logic gate provided in a core logic circuit portion over the first main surface of the semiconductor chip; (c) a first n-channel MISFET making up the CMIS logic gate; (d) a first p-channel MISFET making up the CMIS logic gate; (e) a CMIS buffer provided in a signal output buffer circuit portion over the first main surface of the semiconductor chip; (f) a second n-channel MISFET making up the CMIS buffer and higher in operating voltage than the first n-channel MISFET; (g) a second p-channel MISFET making up the CMIS buffer and higher in operating voltage than the first p-channel MISFET; (h) a CMIS inverter provided in an ESD protection circuit portion over the first main surface of the semiconductor chip; (i) a third n-channel MISFET making up the CMIS inverter and higher in operating voltage than the first n-channel MISFET; and (j) a third p-channel MISFET making up the CMIS inverter and higher in operating voltage than the first p-channel MISFET. Each of the third n-channel MISFET and the third p-channel MISFET has a source/drain asymmetric structure and has a halo region only on the source side.

2. In the semiconductor integrated circuit device in Section 1 above, each of the third n-channel MISFET and the third p-channel MISFET further includes: (x1) a high-concentration drain region; and (x2) a drain extension region deeper than the high-concentration drain region and extended from the drain side to below a gate electrode.

3. In the semiconductor integrated circuit device in Section 1 or 2 above, the gate insulating films of the third n-channel MISFET and the third p-channel MISFET are respectively larger in film thickness than the following gate insulating films: the gate insulating films of the first n-channel MISFET and the first p-channel MISFET.

4. In the semiconductor integrated circuit device in any of Sections 1 to 3, each of the second n-channel MISFET and the second p-channel MISFET has a source/drain asymmetric structure and has a halo region only on the source side.

5. In the semiconductor integrated circuit device in any of Sections 1 to 4, the third n-channel MISFET and the third p-channel MISFET are respectively lower in threshold voltage than the second n-channel MISFET and the second p-channel MISFET.

6. In the semiconductor integrated circuit device in any of Sections 1 to 5 above, each of the third n-channel MISFET and the third p-channel MISFET further includes: (x1) a punch through stopper region provided on the source side and deeper than the halo region.

7. A semiconductor integrated circuit device includes: (a) a semiconductor chip having a first main surface; (b) an n-channel MISFET provided in the first main surface of the semiconductor chip and having a source/drain asymmetric structure. The n-channel MISFET includes: (b1) an n-type high-concentration source region and an n-type high-concentration drain region formed in the first main surface of the semiconductor chip so that they sandwich a gate electrode; (b2) an n-type source extension region provided at an end of the n-type high-concentration source region on the gate electrode side; and (b3) a p-type halo region provided so that it surrounds the n-type source extension region and deeper than the n-type source extension region.

8. In the semiconductor integrated circuit device in Section 7 above, the n-channel MISFET further includes: (b4) an n-type drain extension region deeper than the high-concentration drain region and extended from the drain side to below a gate electrode.

9. In the semiconductor integrated circuit device in Section 7 or 8 above, the n-channel MISFET further includes: (b5) a p-type punch through stopper region provided on the source side and deeper than the p-type halo region.

10. A manufacturing method is for a semiconductor integrated circuit device including: (a) a semiconductor chip having a first main surface; and (b) a source/drain asymmetric n-channel MISFET provided in the first main surface of the semiconductor chip. The source/drain asymmetric n-channel MISFET includes: (b1) a first n-type high-concentration source region and a first n-type high-concentration drain region formed in the first main surface of the semiconductor chip so that they sandwich a first gate electrode; (b2) a first n-type source extension region provided at an end of the first n-type high-concentration source region on the gate electrode side; (b3) a p-type halo region so provided that it surrounds the first n-type source extension region and deeper than the first n-type source extension region; and (b4) a p-type punch through stopper region provided on the source side and deeper than the p-type halo region. The manufacturing method for the semiconductor integrated circuit device includes the step of: (x) introducing the p-type punch through stopper region and the p-type halo region using an identical ion implantation mask.

11. In the manufacturing method for the semiconductor integrated circuit device in Section 10 above, the source/drain asymmetric n-channel MISFET further includes: (b5) a first n-type drain extension region deeper than the first high-concentration drain region and extended from the drain side to below a first gate electrode.

12. In the manufacturing method for the semiconductor integrated circuit device in Section 11 above, the semiconductor integrated circuit device further includes: (c) a source/drain symmetric n-channel MISFET provided in the first main surface of the semiconductor chip. The source/drain symmetric n-channel MISFET includes: (c1) a second n-type high-concentration source region and a second n-type high-concentration drain region formed in the first main surface of the semiconductor chip so that they sandwich a second gate electrode; (c2) a second n-type drain extension region deeper than the second high-concentration drain region; and (c3) a second n-type source extension region deeper than the second high-concentration source region. The manufacturing method for the semiconductor integrated circuit device includes the step of: (y) introducing the first n-type drain extension region and the second n-type source extension region using an identical ion implantation mask.

(Style of Description, Basic Terms, and Usage thereof in This Specification)

1. The description of embodiments in this specification may be divided into multiple sections or the like as required for the sake of convenience. These sections or the like are not independent of or separate from one another unless otherwise explicitly stated. Each section or the like is each part of a single example and one section is the details of part of another or a modification or the like to part or all of another. The repetitive description of a similar part will be omitted as a rule. Each constituent element of the embodiments is not indispensable unless otherwise explicitly stated, the number of constituent elements is theoretically limited, or the constituent element is contextually obviously indispensable.

When a term of “semiconductor device” or “semiconductor integrated circuit device” is used in this specification, it mainly refers to various types of single transistors (active elements) and what is obtained by integrating a resistor, a capacitor, or the like over a semiconductor chip or the like (for example, a single crystal silicon substrate) with them at the center. A representative example of various types of transistors is MISFET (Metal Insulator Semiconductor Field Effect Transistor) typified by MOSFET (Metal Oxide Semiconductor Field Effect Transistor). A representative example of integrated circuitry is CMIS (Complementary Metal Insulator Semiconductor) integrated circuit typified by CMOS (Complementary Metal Oxide Semiconductor) integrated circuit obtained by combining an n-channel MISFET and a p-channel MISFET.

Wafer processes for today's semiconductor integrated circuit devices, that is, LSI (Large Scale Integration) are usually roughly classified into FEOL (Front End of Line) process and BEOL (Back End of Line) process. The FEOL process ranges from carrying-in of silicon wafers as raw material to premetal process (process made up of the formation of an interlayer insulating film or the like between the lower end of an Ml wiring layer and a gate electrode structure, the formation of contact holes, tungsten plug, embedding, and the like) or so. The BEOL process begins with the formation of an M1 wiring layer and ranges to the formation of pad openings in a final passivation film over an aluminum pad electrode or so. (In case of wafer level package process, that process is also included.) In the FEOL process, gate electrode patterning step, contact hole formation step, and the like are micromachining steps calling for especially minute processing. In the BEOL process, meanwhile, via and trench formation step, especially, local wiring in relatively low layers and the like calls for especially minute processing. (Examples of local wiring in relatively low layers are the following fine buried wiring: fine buried wiring of M1 to M3 or so for buried wiring with a configuration of four layers or so and fine buried wiring of M11 to M5 or so for buried wiring with a configuration of 10 layers or so.) “MN (usually, N=1 to 15 or so)” denotes wiring in the Nth layer from bottom. M1 denotes wiring in the first layer and M3 denotes wiring in the third layer.

2. Even when the wording of “X made up of A” or the like is used in the description of the embodiments with respect to material, composition, or the like, what containing an element other than A as one of major constituent elements is not excluded. This applies unless otherwise explicitly stated or it is contextually obviously excluded. Examples will be taken. With respect to component, the above wording means that “X including A as a main component” or the like. A term of “silicon member” or the like is not limited to members of pure silicon and includes SiGe alloys, other multi-element alloys predominantly including silicon, and members containing other additive or the like, needless to add. Similarly, a term of “silicon oxide film,” “silicon oxide insulating film,” or the like includes not only relatively pure undoped silicon dioxide, but also includes the following, needless to add: thermally-oxydized films, such as FSG (Fluorosilicate Glass), TEOS-based silicon oxide, SiOC (Silicon Oxicarbide), or carbon-doped silicon oxide, or OSG (Organosilicate glass), PSG (Phosphorus Silicate Glass), or BPSG (Borophosphosilicate Glass), CVD oxide films, SOG (Spin ON Glass), silica Low-k insulating films (porous insulating films) of application oxide silicon such as NCS (Nano-Clustering Silica) and those obtained by introducing electron holes in a member similar to them, and composite films with any other silicon insulating film containing them as a predominant constituent element, and the like.

One of silicon insulating films regularly used along with silicon oxide insulating films in the field of semiconductor is silicon nitride insulating film. The materials belonging to this family include SiN, SiCN, SiNH, SiCNH, and the like. A term of “silicon nitride” includes both SiN and SiNH unless otherwise explicitly stated. Similarly, a term of “SiCN” includes both SiCN and SiCNH unless otherwise explicitly stated.

SiC has properties similar to those of SiN. SiON should often be classified into silicon oxide insulating films.

The silicon nitride film is heavily used as an etch stop film in the SAC (Self-Aligned Contact) technology. It is also used as a stress applying film in SMT (Stress Memorization Technique).

Similarly, a term of “nickel silicide” usually refers to nickel monosilicide; however, it includes not only relatively pure ones but also alloys, mixed crystals, and the like containing nickel monosilicide as a predominant constituent element. Silicide is not limited to nickel silicide and may be time-tested cobalt silicide, titanium silicide, tungsten silicide, and the like. Aside from Ni (nickel) films, for example, the following nickel alloy films and the like can be used as a metal film for silicidation: Ni—Pt alloy film (alloy film of Ni and Pt), Ni—V alloy film (alloy film of Ni and V), Ni—Pd alloy film (alloy film of Ni and Pd), Ni—Yb alloy film (alloy film of Ni and Yb), Ni—Er alloy film (alloy film of Ni and Er), or the like. These silicides containing nickel as a predominant metallic element will be collectively designated as “nickel silicide.”

3. With respect to graphic forms, positions, attributes, and the like, favorable examples will be taken. However, the invention is not strictly limited to them unless otherwise explicitly stated or the invention is contextually obviously limited to them, needless to add.

4. When reference is made to any specific numeric value or quantity, the specific numeric value or quantity may be exceeded or may be underrun. This applies unless otherwise explicitly stated, any other specific numeric value or quantity is theoretically impermissible, or the specific numeric value or quantity contextually may not be exceeded or underrun.

5. A term of “wafer” usually refers to a single crystal silicon wafer over which a semiconductor integrated circuit device (same as semiconductor device and electronic device) is formed. However, it also includes an epitaxial wafer, a composite wafer of an insulating substrate, such as an SOI substrate or an LCD glass substrate, a semiconductor layer, and the like, and the like.

6. Description will be given to important terms related to the diffuse structure of MISFET, an impurity doped region structure, and the like used in the description of embodiments or the like.

A term of “short channel effects” refers to that as the result of a channel length becoming very short, a drain depletion layer has influence on a source and the threshold voltage of MISFET drops (that is, Vth drop), punch through occurs, or any other like event occurs.

A term of “high-concentration source & drain region” refers to an impurity doped region making up a main part of the source & drain region of MISFET. (The source & drain region refers to “a source region and a drain region” or “a source region or a drain region.”) A term of “high-concentration” indicates that the concentration is relatively high as compared with the “source & drain extension region” described next.

A term of “source & drain extension region” refers to an impurity doped region that is extended beyond the gate electrode-side end of a high-concentration source & drain region and is relatively low in concentration and of an identical conductivity type. DDD regions, LDD regions, and the like are heavily used as a representative source & drain extension region.

A term of “DDD (Double Diffused Drain) region” refers to a source & drain extension region so provided that it surrounds a high-concentration source & drain region and deeper than this region. It has the effect of reducing an electric field in proximity to a drain to reduce the hot carrier effect. At the same time, however, short channel effects become remarkable if it is too deep.

A term of “LDD (Lightly Doped Drain) region” refers to a source & drain extension region that is located at the same depth as a high-concentration source & drain region or shallower than this region. It has the effect of avoiding short channel effects and reducing an electric field in proximity to a drain to reduce the hot carrier effect. At the same time, however, the source/drain resistance and the like are increased.

A term of “halo region” refers to an impurity doped region that surrounds a source & drain extension region and is of the same conductivity type as that of a substrate or a well region and higher in concentration than them. It has the effect of suppressing short channel effects. It is usually introduced by oblique ion implantation from four directions at a relatively large angle.

A term of “punch through stopper region” is an impurity doped region introduced to so deep a portion as an end of a source region on the gate electrode side or the like so that a drain depletion layer does not reach the source region. The punch through stopper region is of the same conductivity type as a halo region and deeper than the halo region.

A term of “source/drain asymmetric structure” refers to that the structure or combination of the impurity doped regions, such as the source and the drain, of MISFET is asymmetric. Such MISFET is designated as “source/drain asymmetric MISFET.” Those simply asymmetric in source/drain area, shape, or the like as planarly viewed from above a semiconductor chip or the like are not a “source/drain asymmetric structure.”

A term of “source/drain symmetric structure” refers to that the structure or combination of the impurity doped regions, such as the source and the drain, of MISFET is symmetric. Such MISFET is designated as “source/drain symmetric MISFET.”

### Details of Embodiments

Further detailed description will be given to embodiments. In each drawing, the same or similar parts will be marked with same or similar codes or reference numerals and the description thereof will not be repeated as a rule.

In the accompanying drawings, hatching or the like may be omitted from even a section when they otherwise complicate the drawing or the section is clearly distinguishable from airspaces. Even in case of a planarly closed hole, the outline in the background may be omitted when it is apparent from explanation or the like or on the other like occasions. Even not a section, hatching may be provided to clearly indicate that it is not an airspace.

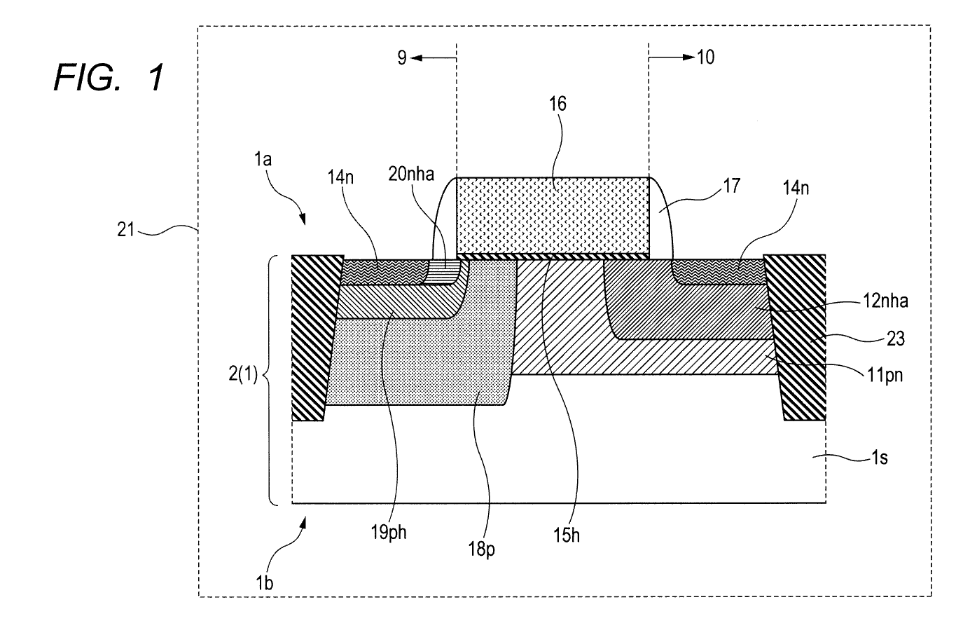

1. Description of High-Breakdown Voltage Source/Drain Asymmetric Structure MISFET (Basic Structure) of Semiconductor Integrated Circuit Device in Embodiment of Invention (Mainly FIG. 1)

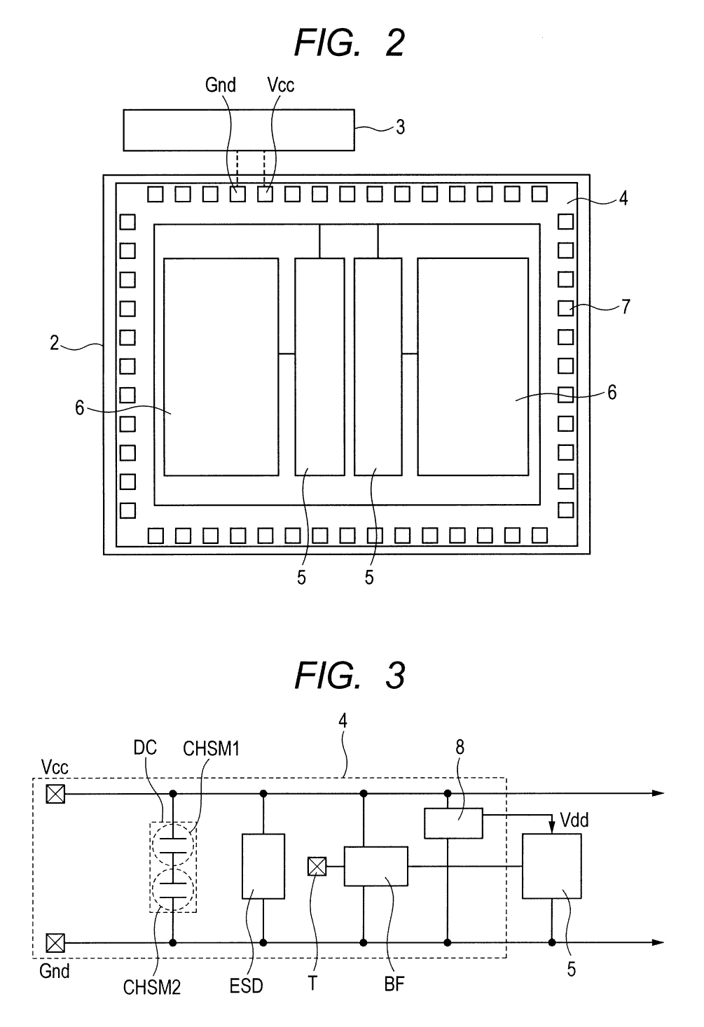

Here, description will be given to a high-breakdown voltage MISFET provided in an interface circuit portion 4 (FIG. 2) in which bonding pads (terminal electrodes over chip) and the like are mainly placed over a semiconductor chip. “High-breakdown voltage” indicates that the breakdown voltage of the device is relatively high. An example of this case is a case where, while a core logic circuit portion 5 (FIG. 2) operates mainly on, for example, 1.2 volts or so, the interface circuit portion 4 operates on 5 volts or so. Therefore, the core logic circuit portion 5 is configured mainly of a low-breakdown voltage MISFET.

In the integrated circuit device in this embodiment, mainly, a CMIS configuration (that is, when there is an n-channel device, there is a p-channel device corresponding thereto) is adopted with respect to various types of MISFETs. Hereafter, concrete description will be given to the device structure with mainly an n-channel device taken as an example. This is because when an n-channel device is described, the structure of and the process for manufacturing a p-channel device can be clearly understood by NP replacement.

FIG. 1 is a device sectional view of an n-channel high-breakdown voltage asymmetric MISFET illustrating as an example of the basic structure of a high-breakdown voltage asymmetric MISFET of a semiconductor integrated circuit device in an embodiment of the invention. Description will be given to the high-breakdown voltage asymmetric MISFET (basic structure) and the like of the semiconductor integrated circuit device in the embodiment of the invention with reference to this drawing.

As illustrated in FIG. 1, the n-channel high-breakdown voltage asymmetric MISFET is formed on the front surface 1a side of an asymmetric high-breakdown voltage MISFET region 21 of, for example, a p-type single crystal silicon substrate. (The front surface 1a is the surface on the opposite side to a back surface 1b.) (The front surface side specifically includes the front surface, over the front surface, and in the front surface.) (The p-type single crystal silicon substrate is a semiconductor chip 2 in the end product and a semiconductor wafer 1 in manufacturing process. The back surface side of the semiconductor chip 2 and the semiconductor wafer 1 is an original substrate portion 1s.) The semiconductor chip 2, semiconductor wafer 1, or the like (hereafter, referred to as “semiconductor substrate or the like”) may wholly or partly have an SOI structure. Aside from a p-type single crystal silicon substrate, the semiconductor substrate or the like may be an n-type single crystal silicon substrate or an epitaxial substrate of each conductivity type as required. Or, it may be a semiconductor substrate of SiGe or the like other than silicon. (Those partly containing them are also included.)

The asymmetric high-breakdown voltage MISFET region 21 (accurately, n-channel asymmetric high-breakdown voltage MISFET region) is surrounded by the following region in the front surface 1a region of the semiconductor chip 2: an element isolation region, such as an STI (Shallow Trench Isolation) insulating film 23. (Any other isolation scheme is also acceptable.) This surrounded region is designated as active region. Over the active region, there is provided a gate electrode 16 (first gate electrode) with a gate insulating film 15h (high-breakdown voltage portion gate insulating film) in between. A side wall spacer insulating film 17 is provided in the periphery of them. In the front surface 1a of the semiconductor chip 2, a relatively deep high-breakdown voltage portion p-well region 11ph is provided throughout the active region (the active region of the n-channel asymmetric high-breakdown voltage MISFET).

Description will be given to an impurity doped region on the drain side 10. The following are provided in the high-breakdown voltage portion p-well region 11ph in the front surface 1a of the semiconductor chip 2 on the drain side 10: a relatively shallow n-type high-concentration drain region 14n (first n-type high-concentration drain region); and an asymmetric n-type drain extension region 12nha formed in such a shape as to surround it and lower in impurity concentration and deeper than the n-type high-concentration drain region 14n. (The asymmetric n-type drain extension region 12nha does not necessarily need be relatively deep; however, the electric field reduction effect is increased with increase in the depth thereof.) This drain extension region 12nha (first drain extension region) is a so-called DDD region. It may be an LDD region but in this case, the electric field reduction effect is reduced as described above. This deep asymmetric n-type drain extension region 12nha relatively largely overlaps with the gate electrode 16 and this enhances the electric field reduction effect at a drain end. (This is because ensuring a large overlap makes it possible to widen the low-concentration LDD region.)

Meanwhile, the following are provided in the high-breakdown voltage portion p-well region 11ph (in proximity to the front surface) in the front surface 1a of the semiconductor chip 2 on the source side 9: a relatively shallow n-type high-concentration source region 14n (first n-type high-concentration source region) ; and an n-type source extension region 20nha (first n-type source extension region) protruded from it toward the gate electrode, lower in concentration than it, and located at the same depth as or shallower than it. This shallow n-type source extension region 20nha is a so-called LDD region. This is intended to introduce a halo region to the source side as described later.

Further, the following is provided in the high-breakdown voltage portion p-well region 11ph in the front surface 1a of the semiconductor chip 2 on the source side 9 so that it surrounds the n-type source extension region 20nha: a p-type halo region 19ph of a high-breakdown voltage source portion deeper than the n-type source extension region 20nha and is of the same conductivity type as that of the high-breakdown voltage portion p-well region 11ph and higher in concentration than it. As mentioned above, the asymmetric structure in which the halo region 19ph is introduced only on the source side is adopted. This obtains the effect of suppressing short channel effects without dropping the drain breakdown voltage, which is difficult with the symmetric structure. With respect to the n-channel MISFET, this is based on the assumption that the following measure is taken as a rule as described later: operation is carried out with the source side grounded and the drain side at power supply voltage; and this asymmetric high-breakdown voltage MISFET is used only for a portion where a current passes only in one direction and the symmetric high-breakdown voltage MISFET is used for a portion where the direction of current is alternated.

The following is provided in the front surface 1a of the semiconductor chip 2 on the source side 9: a p-type punch through stopper region 18p at the same depth as or deeper than the high-breakdown voltage portion p-well region 11ph and higher in impurity concentration than it. (The p-type punch through stopper region 18p is lower in concentration than the p-type halo region 19ph but deeper than the p-type halo region 19ph.) In the asymmetric high-breakdown voltage MISFET, as mentioned above, the punch through stopper region 18p can be provided only on the source side. In this asymmetric high-breakdown voltage MISFET, it is possible to effectively prevent punch through without dropping the drain breakdown voltage.

In this asymmetric high-breakdown voltage MISFET, gate length can be shortened; therefore, the occupied area can be made smaller than in the symmetric high-breakdown voltage MISFET. As a result, the occupied area of a high-breakdown voltage circuit can be reduced as compared with cases where a high-breakdown voltage circuit is configured only of a symmetric high-breakdown voltage MISFET.

2. Description of Basic Configuration, Main Device Structure, Circuit, and System over Semiconductor Integrated Circuit Chip Related to Semiconductor Integrated Circuit Device in Embodiment of Invention (mainly FIG. 2 to FIG. 13)

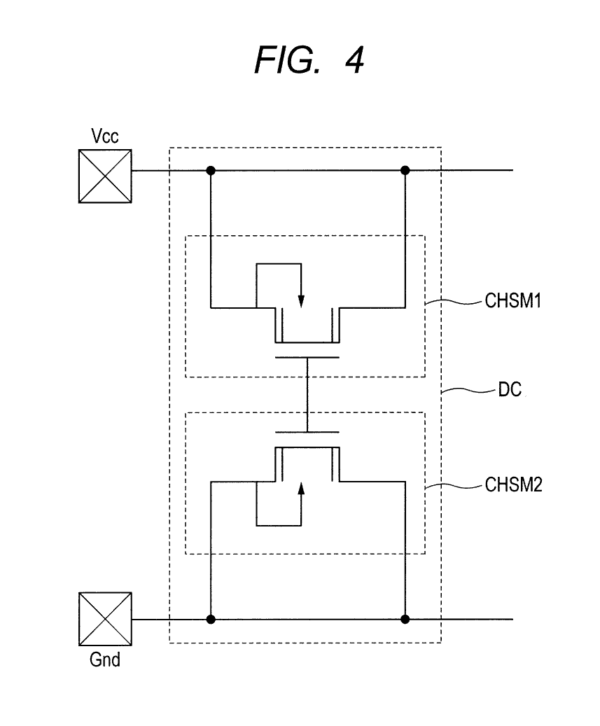

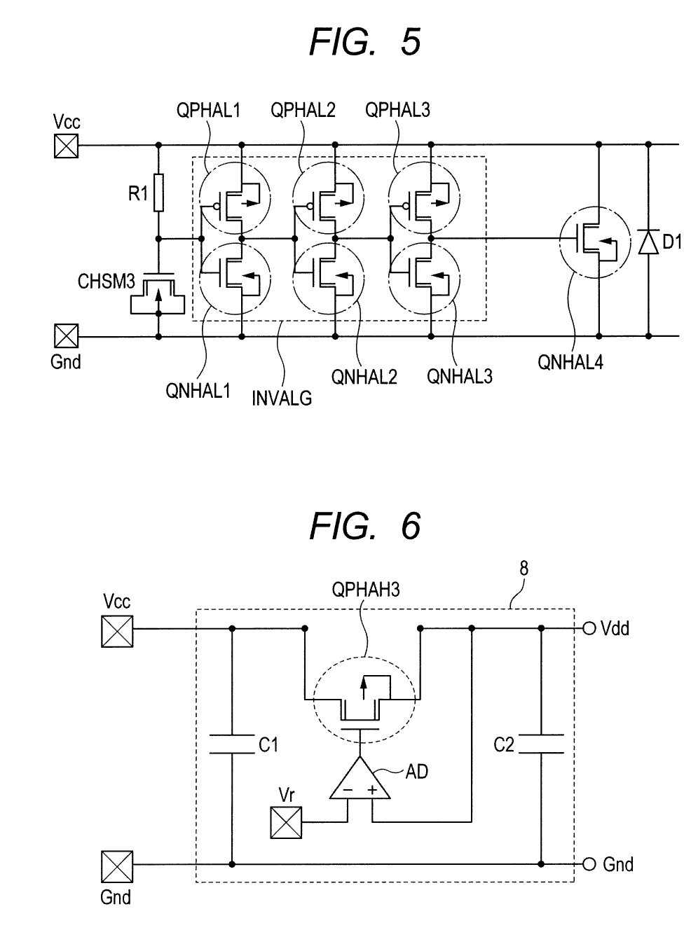

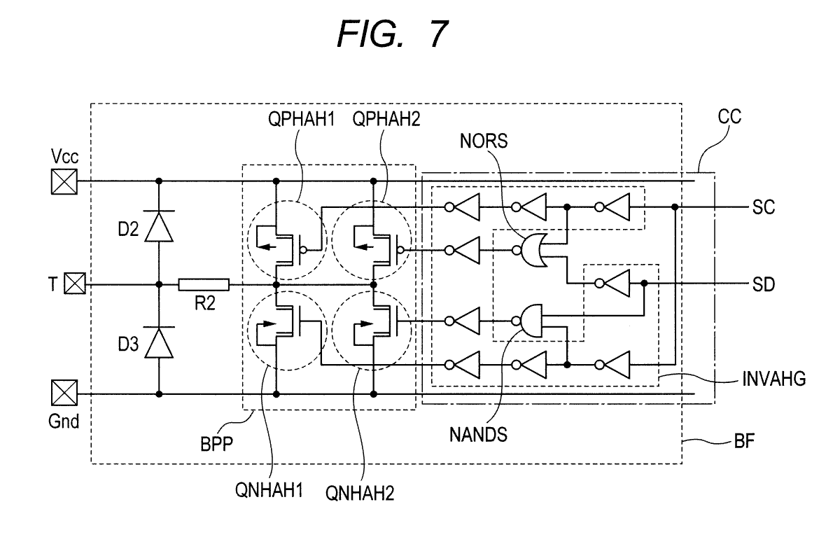

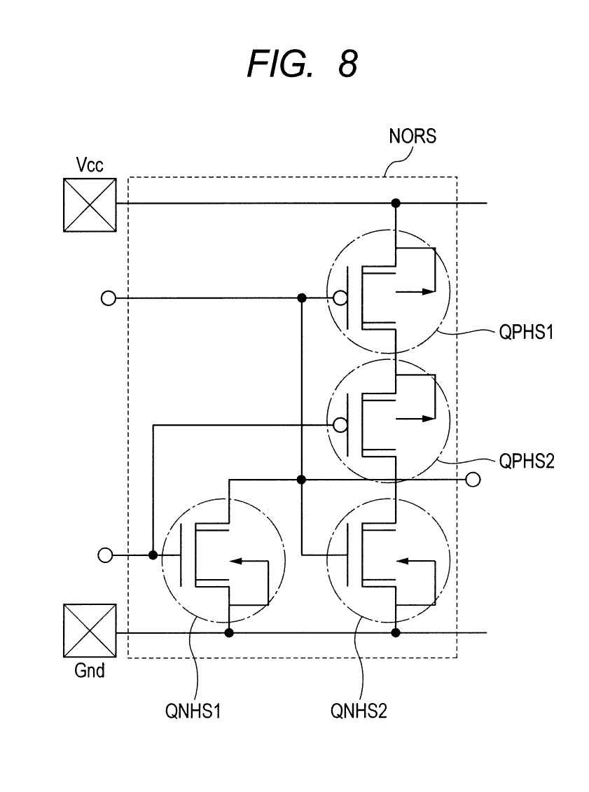

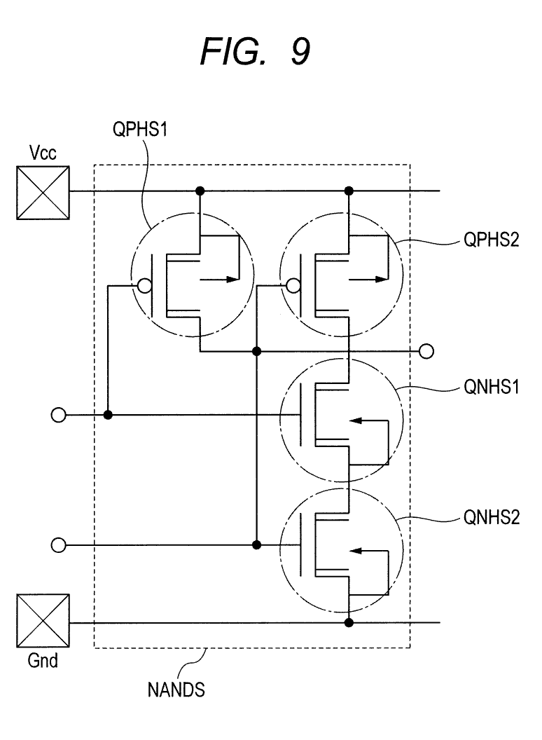

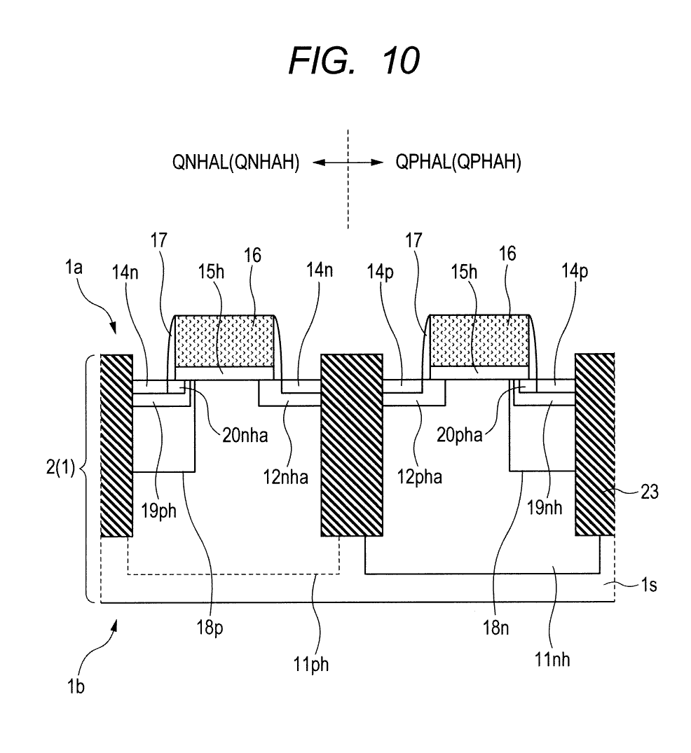

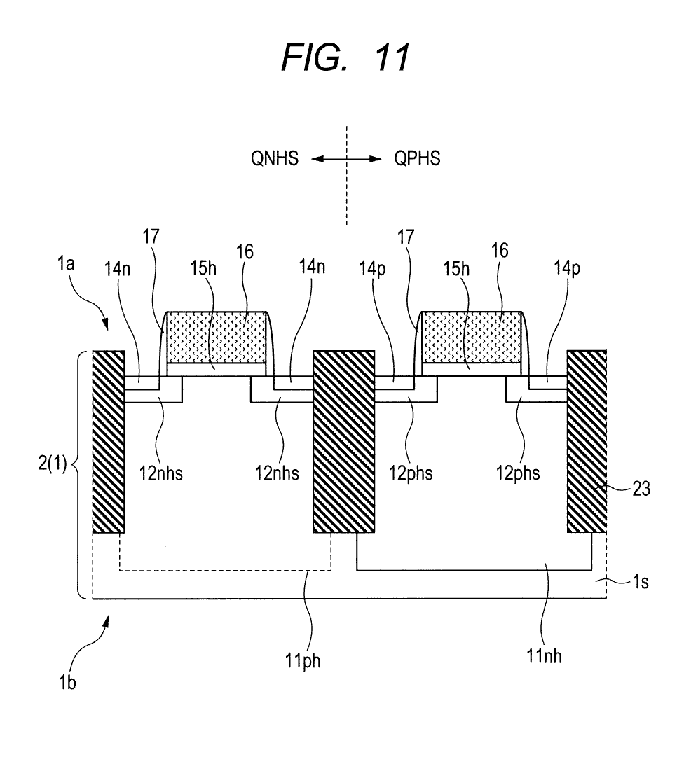

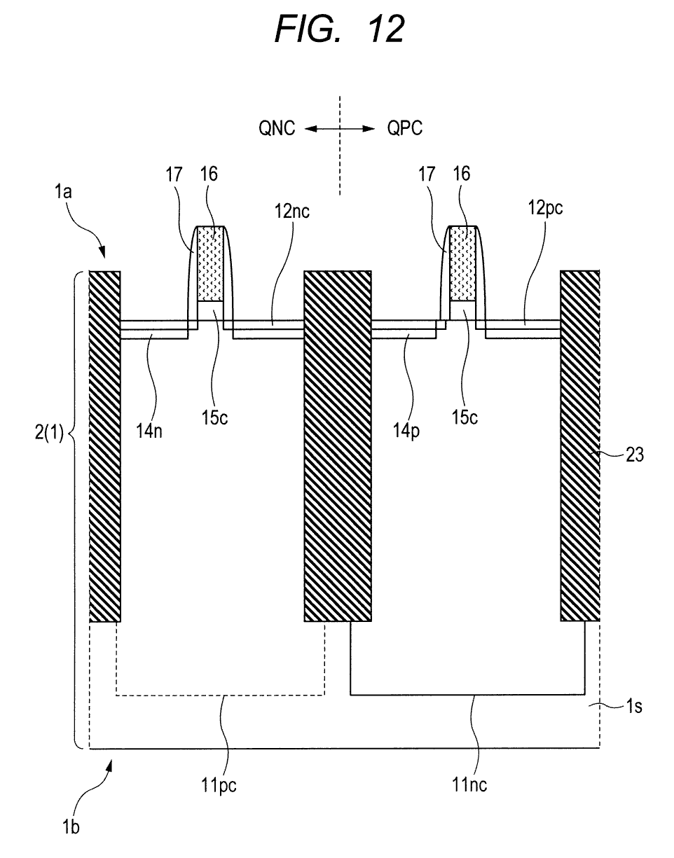

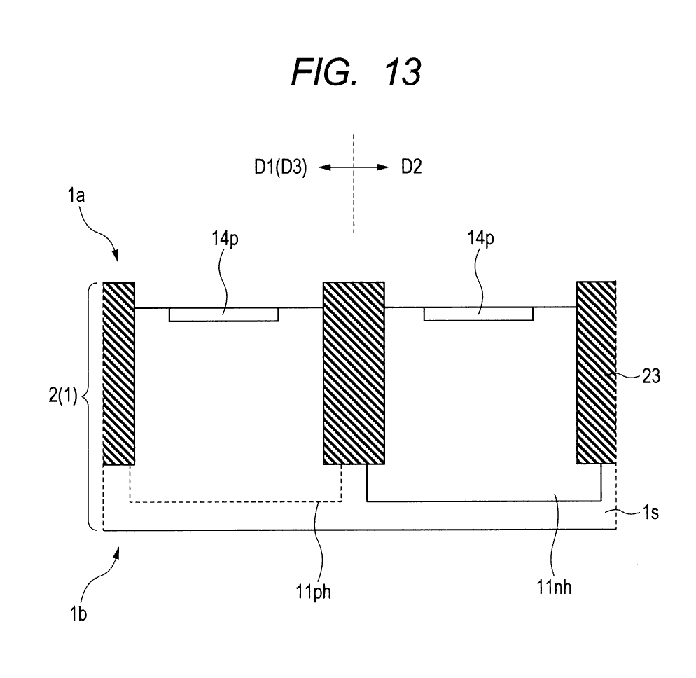

FIG. 2 is a layout diagram of a chip upper surface and the like explaining the basic configuration, main device structure, circuit, and system over a semiconductor integrated circuit chip related to a semiconductor integrated circuit device in the embodiment of the invention. FIG. 3 is a circuit block diagram explaining the relation between the power supply, ESD protection circuit, interface portion, core logic circuit portion, and the like in the layout in FIG. 2. FIG. 4 is a detailed circuit diagram illustrating a concrete circuit example of the decoupling capacitor portion DC in FIG. 3. FIG. 5 is a detailed circuit diagram illustrating a concrete circuit example of the ESD protection circuit portion (ESD) in FIG. 3. FIG. 6 is a detailed circuit diagram illustrating a concrete circuit example of the step-down circuit portion 8 in FIG. 3. FIG. 7 is a detailed circuit diagram illustrating a concrete circuit example of the signal output buffer circuit portion BF in FIG. 3. FIG. 8 is a detailed circuit diagram illustrating a concrete circuit example of the high-breakdown voltage symmetric CMISFET-NOR gate (NORS) in FIG. 7. FIG. 9 is a detailed circuit diagram illustrating a concrete circuit example of the high-breakdown voltage symmetric CMISFET-NAND gate (NANDS) in FIG. 7. FIG. 10 is a device schematic sectional view schematically illustrating the device structures of the following: the n-channel high-breakdown voltage asymmetric high-Vth MISFET (QNHAH), n-channel high-breakdown voltage asymmetric low-Vth MISFET (QNHAL), p-channel high-breakdown voltage asymmetric high-Vth MISFET (QPHAH), and p-channel high-breakdown voltage asymmetric low-VthMISFET (QPHAL) in FIG. 5, FIG. 6, and FIG. 7. FIG. 11 is a device schematic sectional view schematically illustrating the device structures of the following: the n-channel high-breakdown voltage symmetric MISFET (QNHS), p-channel high-breakdown voltage symmetric MISFET (QPHS), and n-channel high-breakdown voltage symmetric MOS capacitors (CHSM1, CHSM2, CHSM3) in FIG. 3, FIG. 4, FIG. 5, FIG. 7, FIG. 8, and FIG. 9. FIG. 12 is a device schematic sectional view schematically illustrating the device structures of the low-breakdown voltage symmetric MISFETs (QNC, QPC) making up the core logic circuit portion 5 in FIG. 2 and FIG. 3. FIG. 13 is a device schematic sectional view schematically illustrating the device structures of the ESD protection diodes (D1, D2, D3) in FIG. 3 and FIG. 7. Description will be given to the basic configuration, main device structure, circuit, and system over the semiconductor integrated circuit chip related to the semiconductor integrated circuit device in this embodiment of the invention with reference to these drawings.

(1) Description of Layout and the Like over Chip (mainly FIG. 2):

Description will be given to the system configuration and the like over the semiconductor integrated circuit chip using the high-breakdown voltage asymmetric MISFET described in Section 1 above with reference to FIG. 2. As illustrated in FIG. 2, multiple bonding pads 7 (terminal electrodes over the chip) are arranged in the interface circuit portion 4 provided in the peripheral portion of the front surface 1a of the semiconductor chip 2. Of them, a high-voltage power supply terminal Vcc (for example, 5-volt external power supply) and a ground terminal Gnd are respectively supplied with power supply potential and ground potential from an external power supply 3. In the internal region of the front surface 1a of the semiconductor chip 2, there are provided, for example, a core logic circuit portion 5, a memory circuit portion 6, and the like. The interface circuit portion 4 is driven with, for example, external high-voltage power supply of mainly 5 volts or so; and the core logic circuit portion 5 and the memory circuit portion 6 are driven mainly with internally stepped-down low-voltage power supply. That is, the semiconductor integrated circuit device uses a multi-voltage power supply system.

A large number of CMIS logic gates are provided in the core logic circuit portion 5, memory circuit portion 6, and the like. They are made up of, for example, a first n-channel MISFET, a first p-channel MISFET, and the like.

(2) Description of each Circuit Block and the Like (mainly FIG. 3 to FIG. 9)

Description will be given to the relation between the power supply terminal Vcc (ground terminal Gnd), ESD protection circuit portion (ESD), interface portion 4, core logic circuit portion 5, and the like in the layout in FIG. 2 with reference to FIG. 3. As illustrated in FIG. 3, there are the power supply terminal Vcc and the ground terminal Gnd in the interface portion 4 and external high-voltage power supply voltage is supplied from them. The following are coupled between the high-voltage power supply potential and the ground potential: a decoupling capacitor portion DC (n-channel high-breakdown voltage symmetric MOS capacitors CHSM1, CHSM2), an ESD protection circuit portion (ESD), a signal output buffer circuit portion BF (I/O buffer and the like), a step-down circuit portion 8, and the like. Low-voltage power supply potential Vdd of, for example, 1.2 volts or so is supplied from the step-down circuit portion 8 and this drives the core logic circuit portion 5 and the like. Output signals from the core logic circuit portion 5 are outputted to an external source from a signal output terminal T through the signal output buffer circuit portion BF. As mentioned above, the signal output buffer circuit portion BF is provided with a CMIS buffer. This CMIS buffer is made up of a second n-channel MISFET (second p-channel MISFET) whose operating voltage is higher than, for example, that of an n-channel MISFET (p-channel MISFET) making up the core logic circuit portion 5.

FIG. 4 illustrates the details of the decoupling capacitor portion DC in FIG. 3. To suppress radiation electromagnetic noise, that is, EMI (Electro-Magnetic Interference) due to fluctuation in power supply voltage, it is necessary to use a decoupling capacitor portion DC with a large capacitance. For this reason, it is desirable to use n-channel high-breakdown voltage symmetric MOS capacitors CHSM1, CHSM2 of high-breakdown voltage MISFET type having a source/drain symmetric structure large in gate length.

FIG. 5 illustrates the details of the ESD protection circuit portion (ESD) in FIG. 3. As illustrated in FIG. 5, for example, the following are coupled between the high-voltage power supply potential and the ground potential: a series coupled circuit of a polysilicon resistor R1 and a capacitor CHSM3 (for example, that having the same structure as the n-channel high-breakdown voltage symmetric MOS capacitors CHSM1, CHSM2 and the like); a high-breakdown voltage asymmetric low-Vth CMISFET inverter group INVALG (group of series coupled multiple inverters) that receives the potential at the intermediate point of this series coupled circuit and is made up of multiple source/drain asymmetric high-breakdown voltage MISFET pairs; an n-channel high-breakdown voltage asymmetric low-Vth MISFET (QNHAL4) that short-circuits the high-voltage power supply potential and the ground potential by the output of the high-breakdown voltage asymmetric low-Vth CMISFET inverter group INVALG; an ESD protection diode Dl; and the like. When power supply voltage is normally applied to this ESD protection circuit portion (ESD), the potential at the intermediate point between the polysilicon resistor R1 and the capacitor CHSM3 is high. As a result, the output of the series coupled multiple inverter group INVALG is low and the shunt MISFET (QNHAL4) is off. As an example of another case, it will be assumed that positive high surge voltage is applied to the high-voltage power supply terminal Vcc side (between it and the ground potential Gnd). In this case, initially, the potential at the intermediate point between the polysilicon resistor R1 and the capacitor CHSM3 is low. As a result, the shunt MISFET (QNHAL4) is on and functions to dissipate surge voltage. Since the time constant determined by the polysilicon resistor R1 and the capacitor CHSM3 is sufficiently large, the time for which the shunt MISFET (QNHAL4) is on is also sufficiently long. As mentioned above, the ESD protection circuit portion (ESD) is provided with a CMIS inverter. This CMIS inverter is made up of, for example, a third n-channel MISFET (third p-channel MISFET) whose operating voltage is higher than an n-channel MISFET (p-channel MISFET) making up the core logic circuit portion 5.

When power supply voltage is normally applied, the ESD protection diode D1 is off. When positive surge voltage is applied to the power supply terminal Vcc relative to the ground terminal Gnd, it operates in the forward direction and functions to dissipate surge voltage.

It is desirable that the high-breakdown voltage asymmetric low-Vth CMISFET inverter group INVALG should be made up of the following: n-channel high-breakdown voltage asymmetric low-Vth MISFETs (QNHAL1, QNHAL2, QNHAL3) and p-channel high-breakdown voltage asymmetric low-Vth MISFETs (QPHAL1, QPHAL2, QPHAL3). Since the ESD protection circuit portion ESD is required to turn on to start protection operation as early as possible, it is effective to use MISFET relatively low in threshold voltage.

In the ESD protection circuit portion, as mentioned above, a multiple-stage inverter INVALG and large-area n-channel MISFETs are generally used to prevent local concentration of electric charges. Adopting asymmetric high-breakdown voltage MISFETs relatively short in gate length for many of these MISFETs makes it possible to significantly reduce the occupied area of the interface circuit portion 4 (or the ESD protection circuit portion).

FIG. 6 illustrates the details of the step-down circuit portion 8 in FIG. 3. As illustrated in FIG. 6, for example, the output of a p-channel high-breakdown voltage asymmetric high-Vth MISFET (QPHAH3) is inputted to a differential amplifier AD together with reference voltage Vr (for example, 1.2 volts). The high-voltage power supply potential Vcc is thereby converted into low-voltage power supply potential Vdd. Decoupling capacitors C1, C2 are placed to prevent problems due to fluctuation in power supply voltage similarly to the foregoing. Needless to add, this circuit may be made up of an n-channel high-breakdown voltage asymmetric high-Vth MISFET in place of the p-channel high-breakdown voltage asymmetric high-Vth MISFET (QPHAH3). The reason why the MISFET relatively high in threshold voltage is used here is to suppress unwanted current.

Detailed description will be given to the signal output buffer circuit portion BF in FIG. 3 with reference to FIG. 7. As illustrated in FIG. 7, for example, the following are coupled between the high-voltage power supply potential Vcc and the ground potential Gnd: an output control circuit CC that operates in response to output signals SC and control signals SD from the core logic circuit portion; a push-pull output buffer BPP thereby controlled; an ESD protection resistor R2, such as a polysilicon resistor, and the like placed between the output terminal of the push-pull output buffer BPP and the signal output terminal T; and the like. In addition, an ESD protection diode D2 and an ESD protection diode D3 are respectively coupled between the high-voltage power supply potential Vcc and the signal output terminal T and between the signal output terminal T and the ground potential Gnd.

The output control circuit CC and the push-pull output buffer BPP are driven by the high-voltage power supply potential Vcc. A high-breakdown voltage symmetric CMISFET-NOR gate (NORS) and a high-breakdown voltage symmetric CMISFET-NAND gate (NANDS) are required to bidirectionally operate. Therefore, it is desirable to make up them of high-breakdown voltage symmetric MISFETs having a source/drain symmetric structure. In the other respects, it is desirable to make up them of high-breakdown voltage asymmetric MISFETs having a source/drain asymmetric structure to reduce the device area. For example, n-channel high-breakdown voltage asymmetric high-VthMISFETs (QNHAH1, QNHAH2) and p-channel high-breakdown voltage asymmetric high-Vth MISFETs (QPHAH1, QPHAH2) can be used. The high-breakdown voltage symmetric CMISFET-NOR gate (NORS) or the high-breakdown voltage symmetric CMISFET-NAND gate (NANDS) is not made up of a high-breakdown voltage asymmetric CMISFET. The reason for this is as follows: there is a possibility that the direction of current between source and drain is switched; and even though a high-breakdown voltage asymmetric CMISFET relatively short in gate length is used, the layout area may contrarily increase because of layout. In case of inviter and the like, meanwhile, there is no possibility that the direction of current between source and drain is switched and the layout area is reduced without fail, it is desirable to use a high-breakdown voltage asymmetric CMISFET.

As mentioned above, MISFETs relatively high in threshold voltage are used for the output control circuit CC and the push-pull output buffer BPP. This is because they are circuits that normally operate at the time of signal output and it is required to reduce the power consumption as much as possible.

This circuit is an output circuit whose driving capability is variable and the following is a brief description of the gist of its operation. When the control signal SD is set to “1,” the pair of inverters making up the push-pull output buffer BPP operates in parallel and operates in a state in which their driving capability is high. When the control signal SD is set to “0,” meanwhile, one inverter of the pair of inverters making up the push-pull output buffer BPP is held in a high impedance state. (This inverter is one that is made up of the n-channel high-breakdown voltage asymmetric high-Vth MISFET (QNHAH2) and the p-channel high-breakdown voltage asymmetric high-Vth MISFET (QPHAH2).) Therefore, the pair of inverters operates in a state in which their driving capability is low.

FIG. 8 and FIG. 9 respectively illustrate the details of the high-breakdown voltage symmetric CMISFET-NOR gate (NORS) and those of the high-breakdown voltage symmetric CMISFET-NAND gate (NANDS) in FIG. 7. It is desirable that these CMIS logic gates (multiinput logic gates) should be made up of, for example, the following as illustrated in FIG. 8 and FIG. 9: n-channel high-breakdown voltage symmetric MISFETs (QNHS1, QNHS2) and p-channel high-breakdown voltage symmetric MISFETs (QPHS1, QPHS2) having a source/drain symmetric structure.

(3) Description of Device and the Like Making up Each Circuit Block and the Like (mainly FIG. 10 to FIG. 13)

Here, schematic description will be given to examples of the concrete cross section structures of the various MISFETs, capacitors, diodes, and the like described up to this point.

FIG. 10 illustrates the schematic cross section structures of an n-channel high-breakdown voltage source/drain asymmetric MISFET and a p-channel high-breakdown voltage source/drain asymmetric MISFET. (Refer to FIG. 1 for concrete detailed structure.) The n-channel high-breakdown voltage source/drain asymmetric MISFET has been already described in detail with reference to FIG. 1. (That described with reference to FIG. 1 is substantially the same except there is not the p-type punch-through stopper region 18p.) Here, description will be given only to the various impurity doped regions in the p-channel high-breakdown voltage source/drain asymmetric MISFET.

As illustrated in FIG. 10, the p-channel high-breakdown voltage asymmetric MISFET is formed on the front surface 1a side of an asymmetric high-breakdown voltage MISFET region 21 (Refer to FIG. 1) of, for example, a p-type single crystal silicon substrate. (The front surface 1a is the surface on the opposite side to a back surface 1b.) (The front surface side specifically includes the front surface, over the front surface, and in the front surface.) (The p-type single crystal silicon substrate is a semiconductor chip 2 in the end product and a semiconductor wafer 1 in manufacturing process. The back surface side of the semiconductor chip 2 and the semiconductor wafer 1 is an original substrate portion 1s.) The asymmetric high-breakdown voltage MISFET region 21 (accurately, p-channel asymmetric high-breakdown voltage MISFET region) is surrounded by the following in the front surface 1a region of the semiconductor chip 2: an element isolation region, such as an STI (Shallow Trench Isolation) insulating film 23. This surrounded region is designated as active region. Over the active region, there is provided a gate electrode 16 with a gate insulating film 15h (high-breakdown voltage portion gate insulating film) in between. A side wall spacer insulating film 17 is provided in the periphery of them. In the front surface 1a of the semiconductor chip 2, a relatively deep high-breakdown voltage portion n-well region 11nh is provided throughout the active region (the active region of the p-channel asymmetric high-breakdown voltage MISFET).

Description will be given to an impurity doped region on the drain side. The following are provided in the high-breakdown voltage portion n-well region 11nh in the front surface 1a of the semiconductor chip 2 on the drain side: a relatively shallow p-type high-concentration drain region 14p; and an asymmetric p-type drain extension region 12pha formed in such a shape as to surround it and lower in impurity concentration and deeper than the p-type high-concentration drain region 14p. (The asymmetric p-type drain extension region 12pha does not necessarily need be relatively deep; however, the electric field reduction effect is increased with increased with the depth thereof.) This drain extension region 12pha is a so-called DDD region. It may be an LDD region but in this case, the electric field reduction effect is reduced as described above.

Meanwhile, the following are provided in the high-breakdown voltage portion n-well region 11nh (in proximity to the front surface) in the front surface 1a of the semiconductor chip 2 on the source side: a relatively shallow p-type high-concentration source region 14p; and a p-type source extension region 20pha protruded from it toward the gate electrode, lower in concentration than it, and located at the same depth as or shallower than it.

Further, the following is provided in the high-breakdown voltage portion n-well region 11nh in the front surface 1a of the semiconductor chip 2 on the source side so that it surrounds the p-type source extension region 20pha: an n-type halo region 19nh of a high-breakdown voltage source portion deeper than the p-type source extension region 20pha and is of the same conductivity type as that of the high-breakdown voltage portion n-well region 11nh and higher in concentration than it. Further, the following is provided in the front surface 1a of the semiconductor chip 2 on the source side so that it surrounds the n-type halo region 19nh: an n-type punch-through stopper region 18n deeper than the n-type halo region 19nhand lower in impurity concentration than it. (The n-type punch-through stopper region 18n is higher in concentration than the high-breakdown voltage portion n-well region 11nh.)

FIG. 11 illustrates the schematic cross section structures of an n-channel high-breakdown voltage symmetric MISFET (QNHS) and a p-channel high-breakdown voltage symmetric MISFET (QPHS). With the accuracy of this description, the semiconductor substrate 2, the element isolation structure, the structures over the front surface 1a of the semiconductor substrate 2, and the like are identical and the description thereof will not be repeated.

As illustrated in FIG. 11, a relatively deep high-breakdown voltage portion p-well region 11ph is formed in the front surface 1a of the semiconductor chip 2 equivalent to the active region of the n-channel high-breakdown voltage symmetric MISFET (QNHS). The following are provided in the front surface 1a of the semiconductor chip 2 on both sides of a gate electrode 16 (second gate electrode): a relatively shallow n-type high-concentration source/drain region 14n (second n-type high-concentration source region, second n-type high-concentration drain region); and a symmetric n-type source/drain extension region 12nhs (second n-type source extension region, second n-type drain extension region) lower in impurity concentration and deeper than it.

Meanwhile, a relatively deep high-breakdown voltage portion n-well region 11nh is formed in the front surface 1a of the semiconductor chip 2 equivalent to the active region of the p-channel high-breakdown voltage symmetric MISFET (QPHS). The following are provided in the front surface 1a of the semiconductor chip 2 on both sides of a gate electrode 16: a relatively shallow p-type high-concentration source/drain region 14p and a symmetric p-type source/drain extension region 12phs lower in impurity concentration and deeper than it.

FIG. 12 illustrates the schematic cross section structures of an n-channel low-breakdown voltage core MISFET (QNC) and a p-channel low-breakdown voltage core MISFET (QPC) in the core logic circuit portion 5. With the accuracy of this description, the semiconductor substrate 2, the element isolation structure, and the like are identical and the description thereof will not be repeated.

As illustrated in FIG. 12, a gate electrode 16 is respectively formed in the front surface 1a of the semiconductor chip 2 in both the active regions with a core logic portion gate insulating film 15c (thinner than the high-breakdown voltage portion gate insulating film 15h) in between. A side wall spacer insulating film 17 is formed in the periphery of them.

A relatively deep core logic portion p-well region 11pc is formed in the front surface 1a of the semiconductor chip 2 equivalent to the active region of the n-channel low-breakdown voltage core MISFET (QNC). The following are provided in the front surface 1a of the semiconductor chip 2 on both sides of the gate electrode 16: a relatively shallow n-type high-concentration source/drain region 14n and a core portion n-type source/drain extension region 12nc lower in impurity concentration and shallower than it. The core portion n-type source/drain extension region 12nc is of a so-called LDD structure. It maybe provided with a DDD structure. However, the short channel effects tend to be prominent with the DDD structure.

Meanwhile, a relatively deep core logic portion n-well region 11nc is formed in the front surface 1a of the semiconductor chip 2 equivalent to the active region of the p-channel low-breakdown voltage core MISFET (QPC). The following are provided in the front surface 1a of the semiconductor chip 2 on both sides of the gate electrode 16: a relatively shallow p-type high-concentration source/drain region 14p and a core portion p-type source/drain extension region 12pc lower in impurity concentration and shallower than it. Similarly to the foregoing, the core portion p-type source/drain extension region 12pc is of a so-called LDD structure. It maybe provided with a DDD structure. However, short channel effects tend to be prominent with the DDD structure.

FIG. 13 illustrates the schematic cross section structures of the ESD protection diodes D1, D2, D3. With the accuracy of this description, the semiconductor substrate 2, the element isolation structure, and the like are identical and the description thereof will not be repeated.

As illustrated in FIG. 13, the following is formed in the front surface 1a of the semiconductor chip 2 equivalent to the active region of the ESD protection diode D1, D3: a relatively deep high-breakdown voltage portion p-well region 11ph (acting as the p-type anode region of the diode). A relatively shallow n-type high-concentration cathode region 14n (an impurity region having the same attributes as those of the n-type high-concentration source/drain region 14n of the high-breakdown voltage MOSFET) is provided in the front surface region thereof.

Meanwhile, a relatively deep high-breakdown voltage portion n-well region 11nh (acting as the n-type cathode region of the diode) is formed in the front surface 1a of the semiconductor chip 2 equivalent to the active region of the ESD protection diode D2. A relatively shallow p-type high-concentration anode region 14p (an impurity region having the same attributes as those of the p-type high-concentration source/drain region 14p of the high-breakdown voltage MOSFET) is provided in the front surface region thereof.

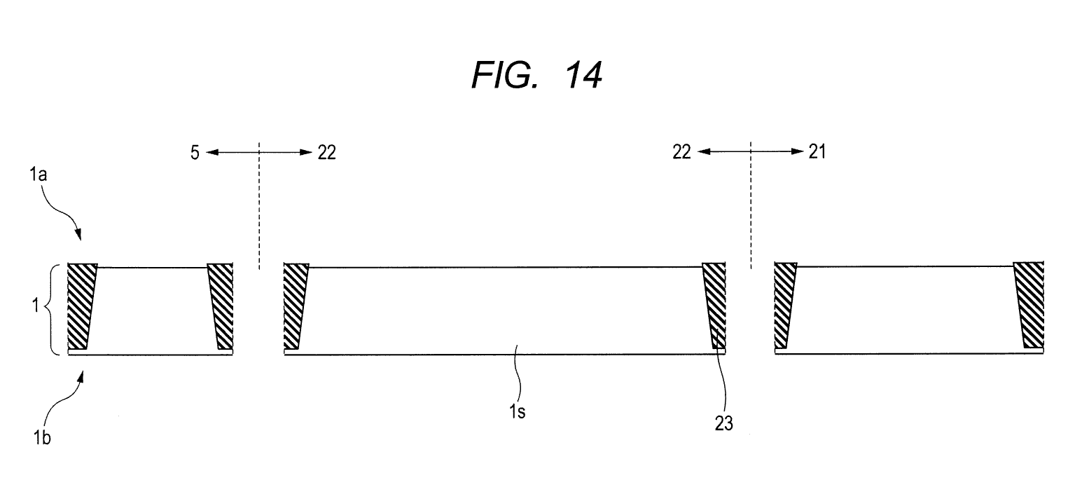

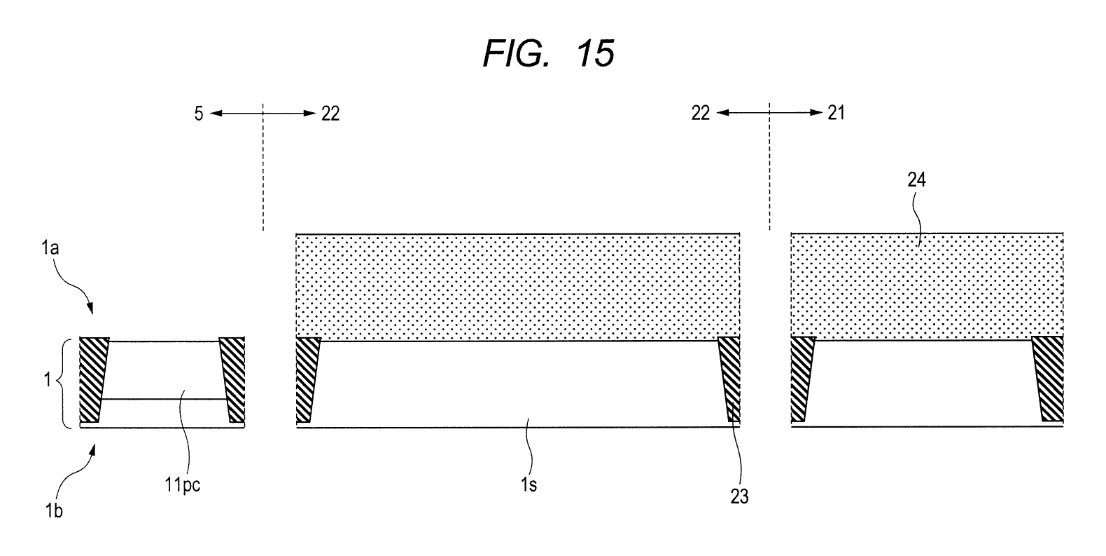

3. Description of Main Part of Wafer Process (Basic Process) Related to Semiconductor Integrated Circuit Device and Manufacturing Method therefor in Embodiment of Invention (mainly FIG. 14 to FIG. 27)

In the following description of the process, only the n-channel device region will be taken as a rule with respect to each region of the following for the above-mentioned reasons: the core logic circuit portion 5 (low-breakdown voltage portion), symmetric high-breakdown voltage MISFET region 22 (high-breakdown voltage portion), asymmetric high-breakdown voltage MISFET region 21 (high-breakdown voltage portion) (FIG. 14 and the like), and the like.

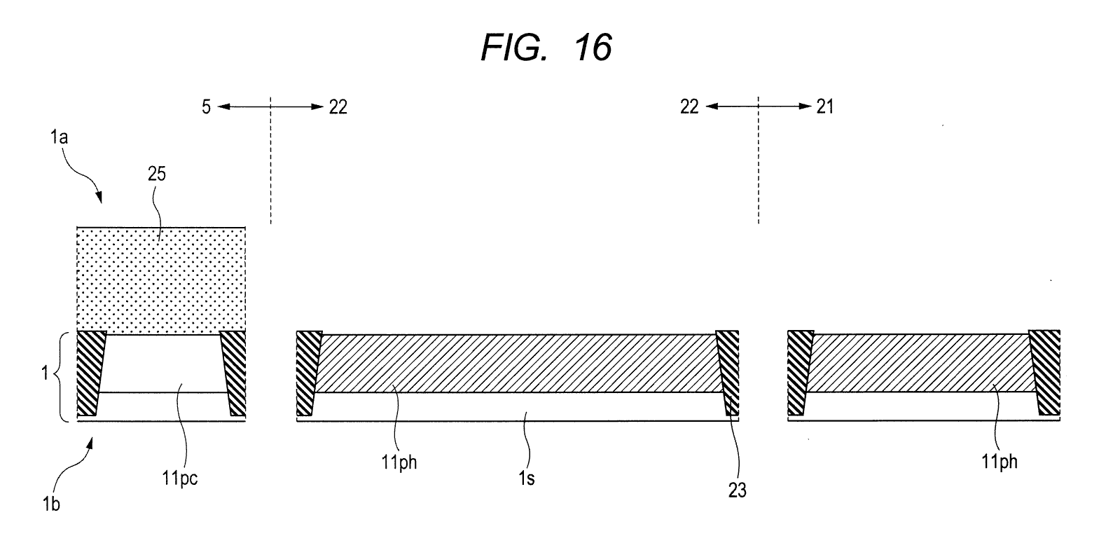

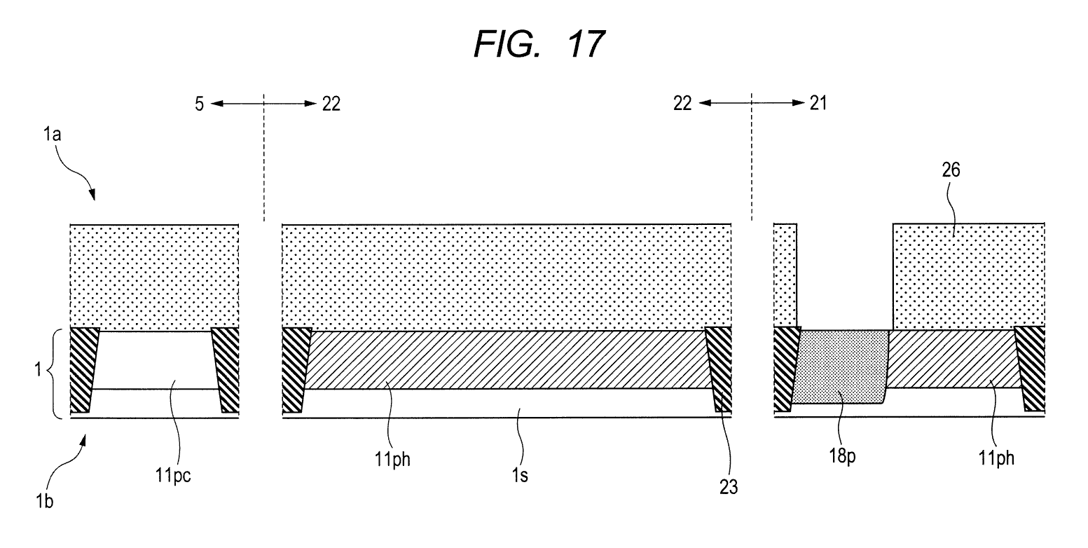

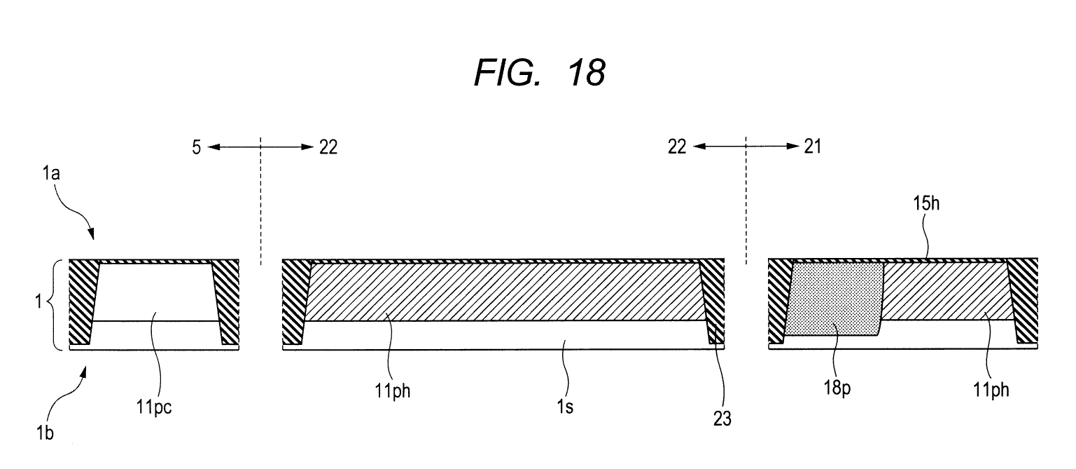

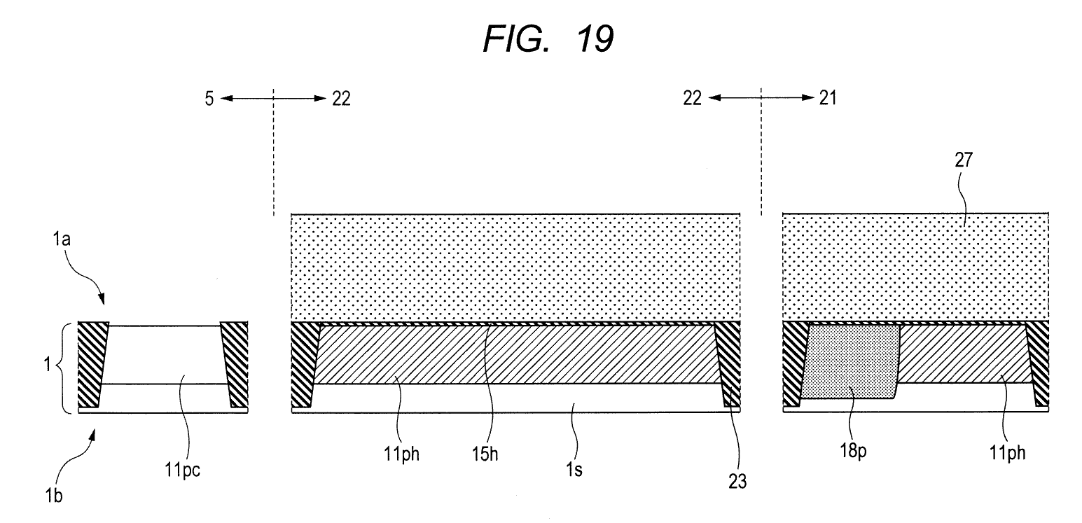

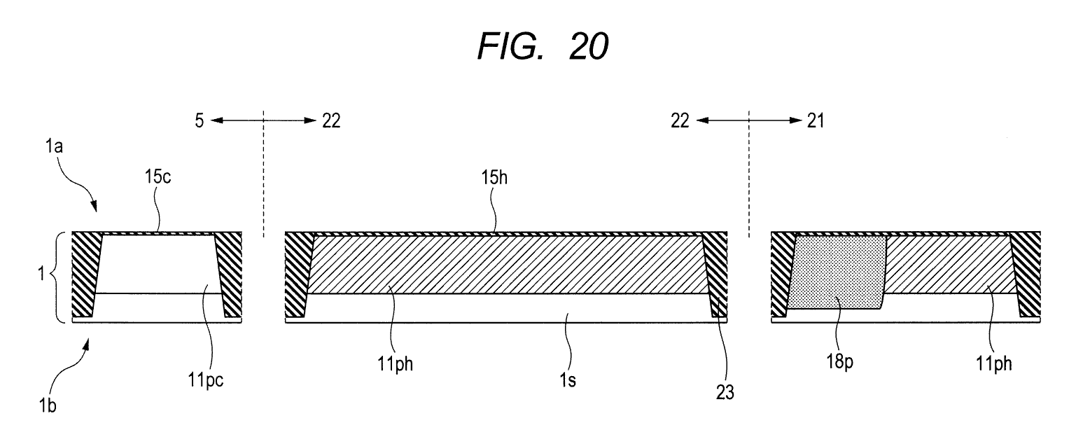

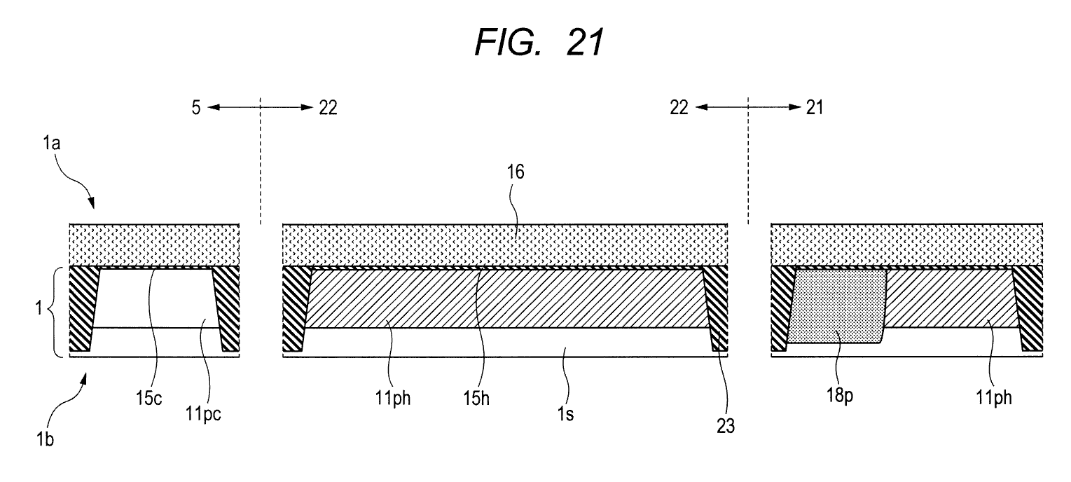

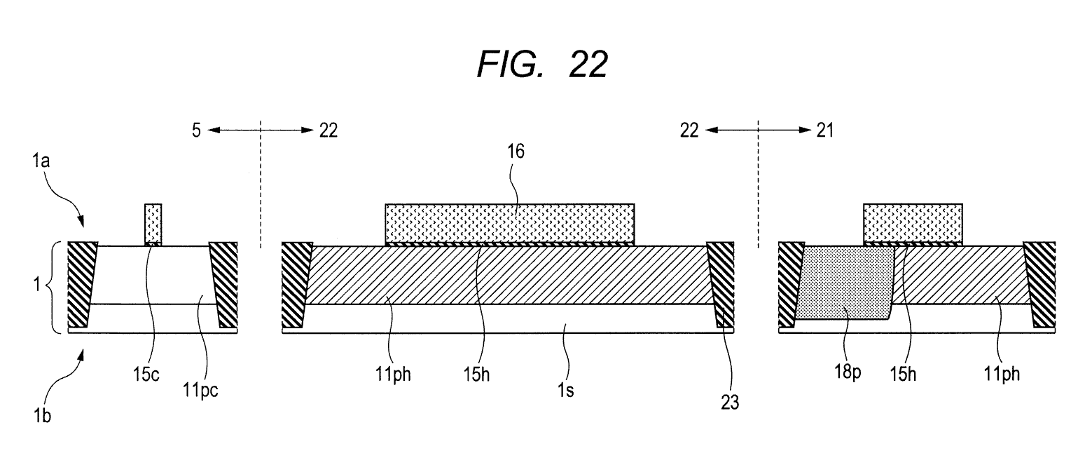

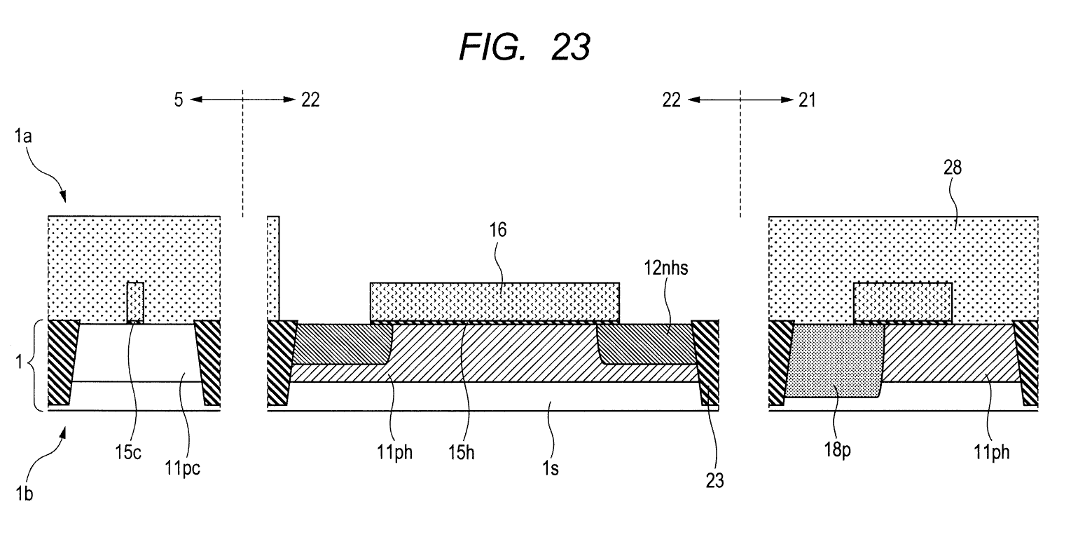

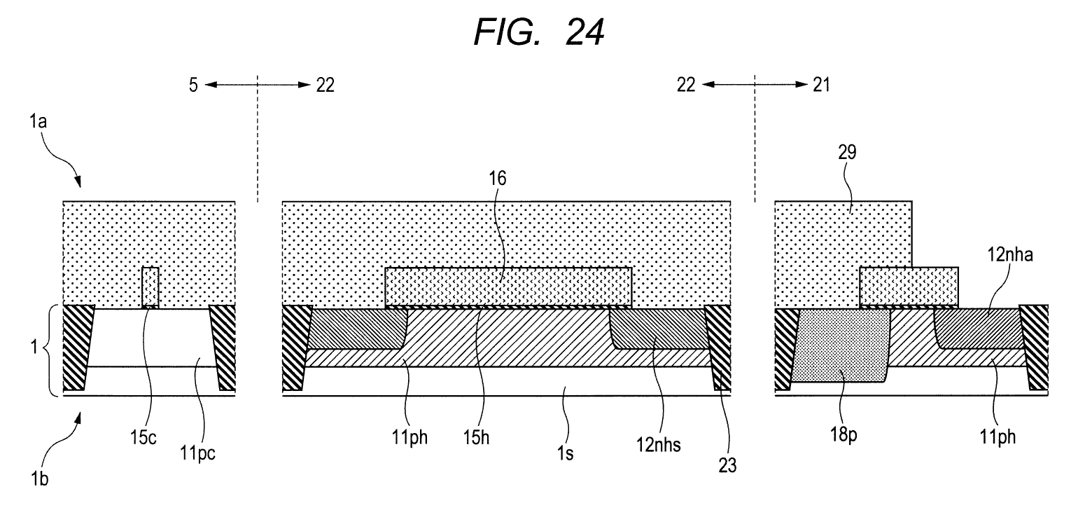

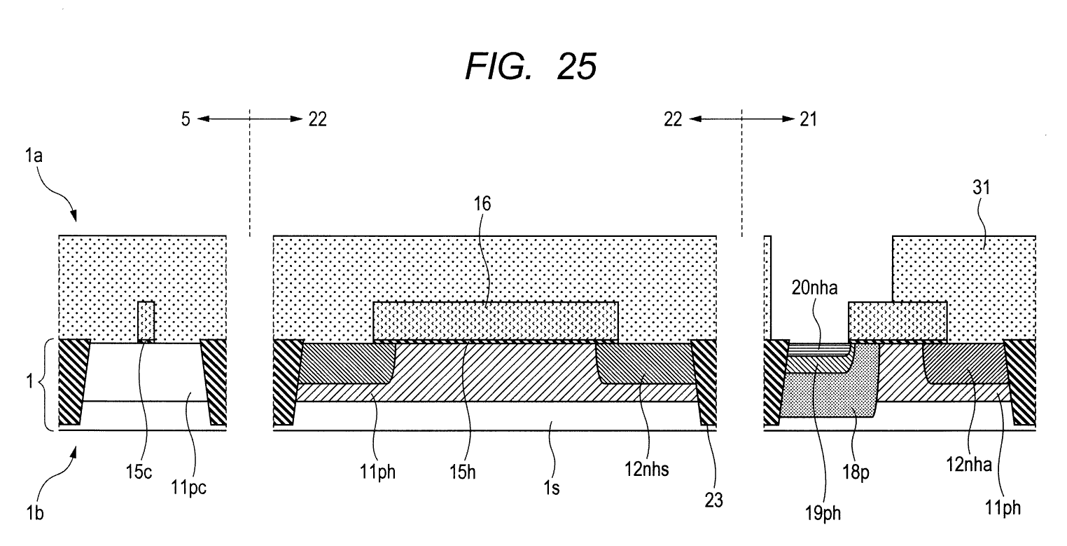

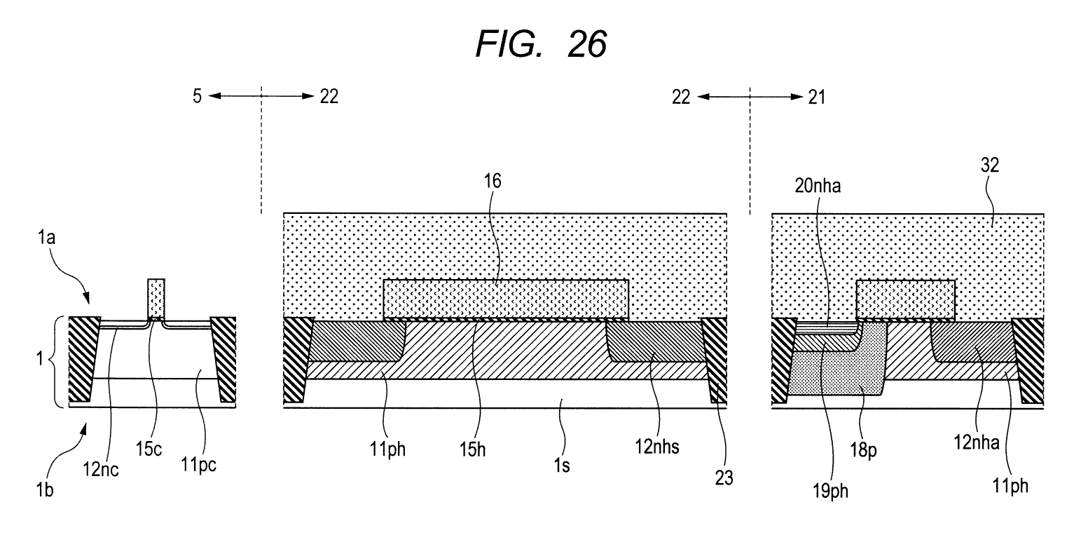

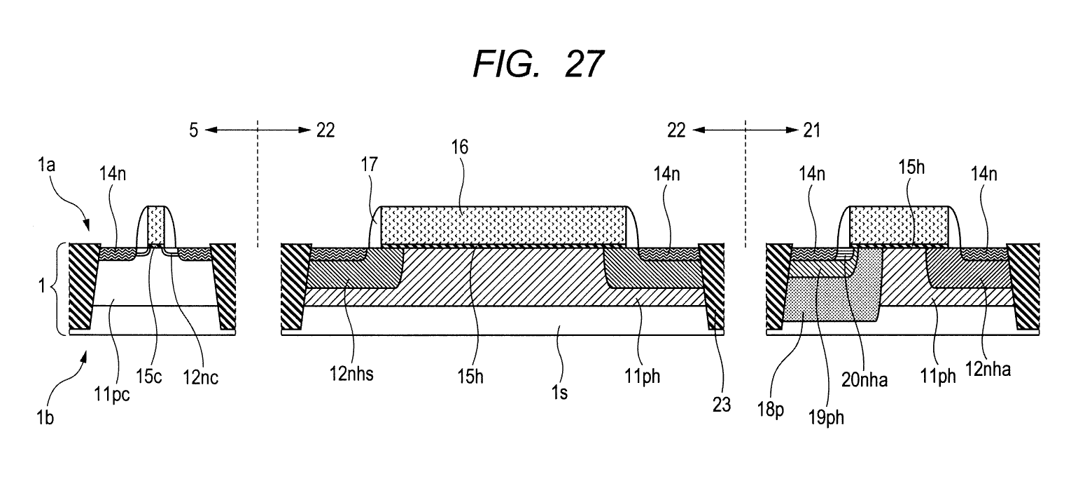

FIG. 14 is a wafer partial sectional view explaining a main part of a wafer process (basic process) related to a semiconductor integrated circuit device and a manufacturing method therefor in an embodiment of the invention (element isolation region formation step). FIG. 15 is a wafer partial sectional view explaining a main part of the wafer process (basic process) related to the semiconductor integrated circuit device and the manufacturing method therefor in the embodiment of the invention (step of introducing p-well in low-breakdown voltage core logic circuit portion). FIG. 16 is a wafer partial sectional view explaining a main part of the wafer process (basic process) related to the semiconductor integrated circuit device and the manufacturing method therefor in the embodiment of the invention (step of introducing p-well in high-breakdown voltage portion). FIG. 17 is a wafer partial sectional view explaining a main part of the wafer process (basic process) related to the semiconductor integrated circuit device and the manufacturing method therefor in the embodiment of the invention (p-type punch through stopper region introduction step). FIG. 18 is a wafer partial sectional view explaining a main part of the wafer process (basic process) related to the semiconductor integrated circuit device and the manufacturing method therefor in the embodiment of the invention (step of forming gate insulating film in high-breakdown voltage portion). FIG. 19 is a wafer partial sectional view explaining a main part of the wafer process (basic process) related to the semiconductor integrated circuit device and the manufacturing method therefor in the embodiment of the invention (step of removing gate insulating film from low-breakdown voltage portion). FIG. 20 is a wafer partial sectional view explaining a main part of the wafer process (basic process) related to the semiconductor integrated circuit device and the manufacturing method therefor in the embodiment of the invention (step of forming gate insulating film in low-breakdown voltage portion). FIG. 21 is a wafer partial sectional view explaining a main part of the wafer process (basic process) related to the semiconductor integrated circuit device and the manufacturing method therefor in the embodiment of the invention (gate electrode film formation step). FIG. 22 is a wafer partial sectional view explaining a main part of the wafer process (basic process) related to the semiconductor integrated circuit device and the manufacturing method therefor in the embodiment of the invention (gate electrode patterning step). FIG. 23 is a wafer partial sectional view explaining a main part of the wafer process (basic process) related to the semiconductor integrated circuit device and the manufacturing method therefor in the embodiment of the invention (symmetric n-type source/drain extension region introduction step). FIG. 24 is a wafer partial sectional view explaining a main part of the wafer process (basic process) related to the semiconductor integrated circuit device and the manufacturing method therefor in the embodiment of the invention (asymmetric n-type drain extension region introduction step). FIG. 25 is a wafer partial sectional view explaining a main part of the wafer process (basic process) related to the semiconductor integrated circuit device and the manufacturing method therefor in the embodiment of the invention (n-type source extension region and p-type halo region introduction step). FIG. 26 is a wafer partial sectional view explaining a main part of the wafer process (basic process) related to the semiconductor integrated circuit device and the manufacturing method therefor in the embodiment of the invention (step of introducing n-type extension region in low-breakdown voltage portion). FIG. 27 is a wafer partial sectional view explaining a main part of the wafer process (basic process) related to the semiconductor integrated circuit device and the manufacturing method therefor in the embodiment of the invention (step of introducing high-concentration n-type source/drain region common to each part). Description will be given to main parts of the wafer process (basic process) related to the semiconductor integrated circuit device and the manufacturing method therefor in the embodiment of the invention with reference to these drawings.

As illustrated in FIG. 14, first, an element isolation 23, such as STI (Shallow Trench Isolation), is formed in correspondence with the following in the front surface 1a of, for example, a p-type single crystal silicon wafer 1 (1s): a core logic circuit portion 5 (low-breakdown voltage portion), a symmetric high-breakdown voltage MISFET region 22 (high-breakdown voltage portion), an asymmetric high-breakdown voltage MISFET region 21 (high-breakdown voltage portion), and the like.

As illustrated in FIG. 15, subsequently, a core logic portion p-well region 11pc is formed in the core logic circuit portion 5 (low-breakdown voltage portion) by ion implantation or the like. At this time, a resist film 24 for core logic portion p-well region introduction is used as an ion implantation mask. An example of preferable conditions for implantation into the n-channel MISFET portion and the like is as follows: ion species: boron, implantation energy: 200 keV to 400 keV, dose amount: 1×10¹²/cm² to 1×10¹³/cm² or so, implantation method: vertical implantation, and the like.

As illustrated in FIG. 16, subsequently, a high-breakdown voltage portion p-well region 11ph is introduced in the symmetric high-breakdown voltage MISFET region 22 (high-breakdown voltage portion) and the asymmetric high-breakdown voltage MISFET region 21 (high-breakdown voltage portion). This is done by, for example, ion implantation or the like using a resist film 25 for high-breakdown voltage portion p-well region introduction as anion implantation mask. An example of preferable conditions for implantation into the n-channel MISFET portion and the like is as follows: ion species: boron, implantation energy: 200 keV to 400 keV, dose amount: 1×10¹²/cm² to 1×10¹³/cm² or so, implantation method: vertical implantation, and the like.

As illustrated in FIG. 17, subsequently, a p-type punch through stopper region 18p is introduced in the source side of the asymmetric high-breakdown voltage MISFET region 21 (high-breakdown voltage portion). This is done by, for example, ion implantation or the like using a resist film 26 for p-type punch through stopper region introduction as an ion implantation mask. An example of preferable conditions for implantation into the n-channel MISFET portion and the like is as follows: ion species: boron, implantation energy: 60 keV or so, dose amount: 1×10¹²/cm² to 1×10¹³/cm or so (so set that threshold voltage is not excessively increased), implantation method: vertical implantation, and the like.

As illustrated in FIG. 18, subsequently, a high-breakdown voltage portion gate insulating film 15h is formed in the silicon surface of the front surface 1a of the semiconductor wafer 1 by, for example, thermal oxidation (CVD is also acceptable). When a 5-volt system is assumed, an example of preferable thickness is 15 nm or so.

As illustrated in FIG. 19, subsequently, the gate insulating film 15h in the core logic circuit portion 5 is removed by, for example, hydrofluoric acid etchant or the like using a resist film 27 for gate insulating film removal as a mask.

As illustrated in FIG. 20, subsequently, the following is formed in the silicon surface of the front surface 1a of the semiconductor wafer 1 in the core logic circuit portion 5 by, for example, thermal oxidation (CVD is also acceptable): a core logic portion gate insulating film 15c thinner than the high-breakdown voltage portion gate insulating film 15h. When a 1.2-volt system is assumed, an example of preferable thickness is 2 nm to 3 nm or so.

As illustrated in FIG. 21, subsequently, a gate electrode material film 16 is formed on the front surface 1a side of the semiconductor wafer 1.

As illustrated in FIG. 22, subsequently, the gate electrode material film 16 is patterned by ordinary lithography to form the following: the respective gate electrodes 16 of the core MIS FET, the high-breakdown voltage source/drain symmetric MIS FET, and the high-breakdown voltage source/drain asymmetric MISFET. When a 65-nm technology node is taken as an example, an example of preferable gate length of each gate electrode is as follows: core MISFET: 65 nm or so, high-breakdown voltage source/drain symmetric MISFET: 1 micrometer or so, high-breakdown voltage source/drain asymmetric MISFET: 0.4 micrometers or so to 0.6 micrometers or so.

As illustrated in FIG. 23, subsequently, a symmetric n-type source/drain extension region 12nhs is introduced by, for example, ion implantation or the like using a resist film for symmetric n-type source/drain extension region introduction as an ion implantation mask. An example of preferable conditions for implantation into the n-channel MISFET portion and the like is as follows: ion species: phosphorus, implantation energy: 50 keV to 70 keV or so, dose amount: 1×10¹⁴/cm² to 1×10¹⁵/m or so, implantation method: oblique implantation (oblique angle: for example, 30 to 45 degrees or so), and the like.

As illustrated in FIG. 24, subsequently, an asymmetric n-type drain extension region 12nha is introduced only in the drain side of the asymmetric high-breakdown voltage MISFET region 21. This is done by, for example, ion implantation or the like using a resist film for asymmetric n-type drain extension region introduction as an ion implantation mask. An example of preferable conditions for implantation into the n-channel MISFET portion and the like is as follows: ion species: phosphorus, implantation energy: 50 keV to 70 keV or so, dose amount: 1×10¹⁴/cm² to 1×10¹⁵/cm² or so, implantation method: oblique implantation (oblique angle: for example, 30 to 45 degrees or so), and the like.

As illustrated in FIG. 25, subsequently, a p-type halo region 19ph and an n-type source extension region 20nha are introduced in the high-breakdown voltage source portion. This is done by, for example, ion implantation or the like using a resist film 31 for n-type source extension region and p-type halo region introduction as an ion implantation mask. An example of preferable implantation conditions for the p-type halo region 19ph on the source side of the n-channel MISFET portion is as follows: ion species: boron, implantation energy: 10 keV to 15 keV or so, dose amount: 5×10¹²/cm² to 5×10¹³/cm² or so, implantation method: oblique implantation (oblique angle: for example, 30 to 45 degrees or so), and the like.

An example of preferable implantation conditions for the n-type source extension region 20nha on the source side of the n-channel MISFET portion is as follows: ion species: arsenic, implantation energy: 20 keV or so, dose amount: 1×10¹³/cm² to 2×10¹³/cm² or so, implantation method: vertical implantation, and the like.

As illustrated in FIG. 26, substantially, a core portion n-type source/drain extension region 12nc is introduced by, for example, ion implantation or the like using a resist film 32 for core portion source/drain extension region introduction as an ion implantation mask. An example of preferable implantation conditions for the core portion n-type source/drain extension region 12nc in the n-channel MISFET portion is as follows: ion species: arsenic, implantation energy: 5 keV to 10 keV or so, dose amount: 1×10¹⁴/cm² to 2×10¹⁵/cm² or so, implantation method: vertical implantation, and the like.

As illustrated in FIG. 27, subsequently, an n-type high-concentration source/drain region 14n is introduced into the respective n-channel MISFET portions of the following by, for example, ion implantation or the like: the core logic circuit portion 5, symmetric high-breakdown voltage MISFET region 22, and asymmetric high-breakdown voltage MISFET region 21. An example of preferable conditions for this implantation is as follows: ion species: arsenic, implantation energy: 5 keV to 10 keV or so, dose amount: 1×10¹⁵/cm² to 1×10¹⁶/cm² or so, implantation method: vertical implantation, and the like.

4. Description of First Device Modification (Punch Through Stopper Omitted Structure) to High-Breakdown Voltage Asymmetric MISFET (Basic Structure) (Refer to mainly FIG. 28 and FIG. 14 to FIG. 27 except FIG. 17.)

In this example, the impurity doped structure is substantially the same as that in FIG. 27. When the n-channel MISFET portion in the asymmetric high-breakdown voltage MISFET region 21 is taken as an example, this modification is characterized in that the p-type punch through stopper region 18p is omitted. Therefore, the n-type punch through stopper region in the p-channel MISFET portion is also omitted.

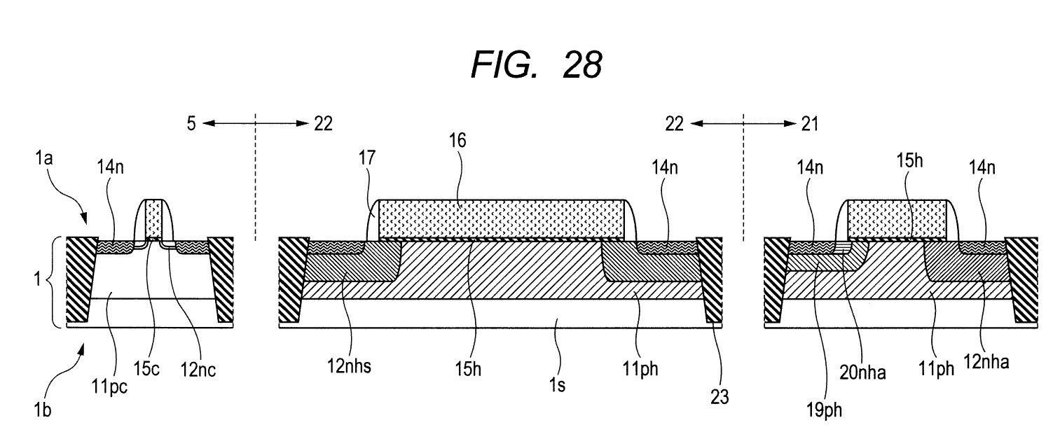

FIG. 28 is a wafer partial sectional view of the first device modification (punch through stopper omitted structure) corresponding to FIG. 27 (step of introducing high-concentration n-type source/drain region common to each part). Description will be given to the first device modification (punch through stopper omitted structure) to the high-breakdown voltage asymmetric MISFET (basic structure) with reference to this drawing.

In terms of process, the modification can be obtained just by omitting the step in FIG. 17 from FIG. 14 to FIG. 27 as illustrated in FIG. 28.

5. Description of First Process Modification (Process in which Introduction of Punch Through Stopper & Source is Common) to Basic Process (Refer to mainly FIG. 29 and FIG. 14 to FIG. 27 except FIG. 17 and FIG. 25.)

Also in this example, the impurity doped structure is substantially the same as that in FIG. 27. When the n-channel MISFET portion in the asymmetric high-breakdown voltage MISFET region 21 is taken as an example, this modification is characterized in that: for the p-type punch through stopper region 18p, the resist film 31 for n-type source extension region and p-type halo region introduction is used as an ion implantation mask.

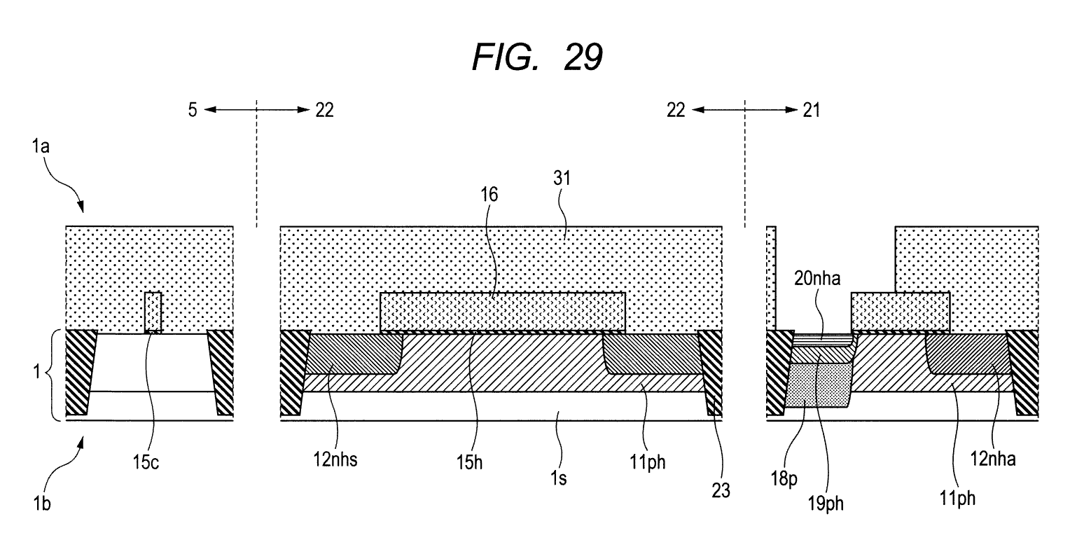

FIG. 29 is a wafer partial sectional view of the first process modification (process in which introduction of punch through stopper & source is common) corresponding to FIG. 25 (p-type punch through stopper region, n-type source extension region, and p-type halo region introduction step). Description will be given to the first process modification (process in which introduction of punch through stopper & source is common) to the basic process with reference to this drawing.

In terms of process, this modification can be obtained just by skipping the step in FIG. 17 and introducing a punch through stopper at the step in FIG. 25 in FIG. 14 to FIG. 27 as illustrated in FIG. 29.

6. Description of Second Process Modification (Process in which Implantation of Source/Drain in High-Breakdown Voltage Symmetric MISFET is Common to Drain Extension in Asymmetric MISFET) to Basic Process (Refer to mainly FIG. 30 and FIG. 14 to FIG. 27 except FIG. 23 and FIG. 24.)

When the n-channel MISFET portion is taken as an example, this example is obtained by making the following common: introduction of the symmetric n-type source/drain extension region 12nhs in the symmetric high-breakdown voltage MISFET region 22 and introduction of the asymmetric n-type drain extension region 12nha in the asymmetric high-breakdown voltage MISFET region 21.

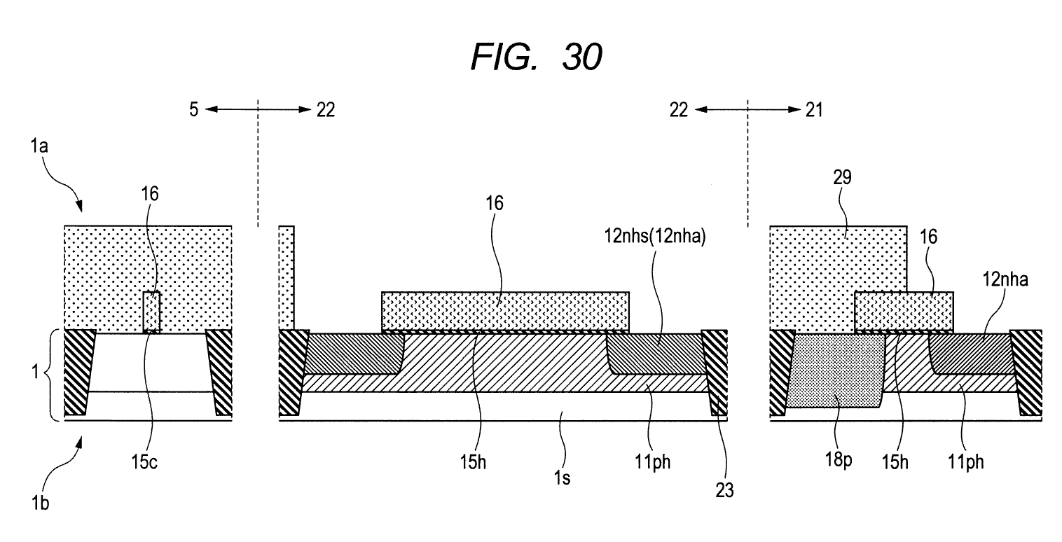

FIG. 30 is a wafer partial sectional view of the second process modification (process in which introduction of source/drain in high-breakdown voltage symmetric MISFET is common to drain extension in asymmetric MISFET) corresponding to FIG. 24 (symmetric n-type source/drain extension region and asymmetric n-type drain extension region introduction step). Description will be given to the second process modification (process in which interlocution of source/drain in high-breakdown voltage symmetric MISFET is common to drain extension in asymmetric MISFET) to the basic process with reference to this drawing.

In terms of process, this modification can be obtained just by, for example, taking the following measure in FIG. 14 to FIG. 27: the step in FIG. 23 is skipped as illustrated in FIG. 30 and at the step in FIG. 24, the resist film 29 for asymmetric n-type drain extension region introduction is changed as illustrated in FIG. 30.

7. Detailed Description of Punch Through Stopper Introduction Step (FIG. 17) in Basic Process (Multi-Vth) (Refer to Mainly FIG. 31 to FIG. 33 and FIG. 14 to FIG. 27.)

This description is equivalent to the detailed description of the step in FIG. 17. In the description given with reference to FIG. 17, the threshold voltage of the asymmetric high-breakdown voltage MISFET is single. In actuality, however, there are often multiple threshold voltages (multi-Vth).

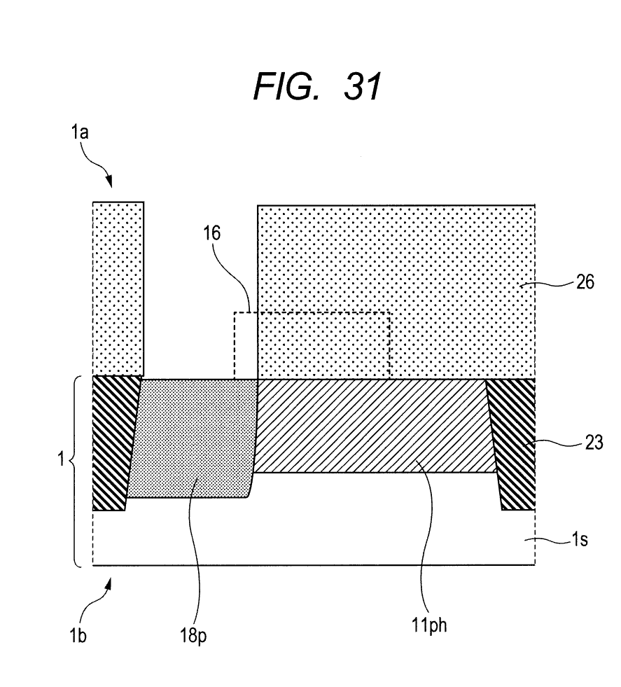

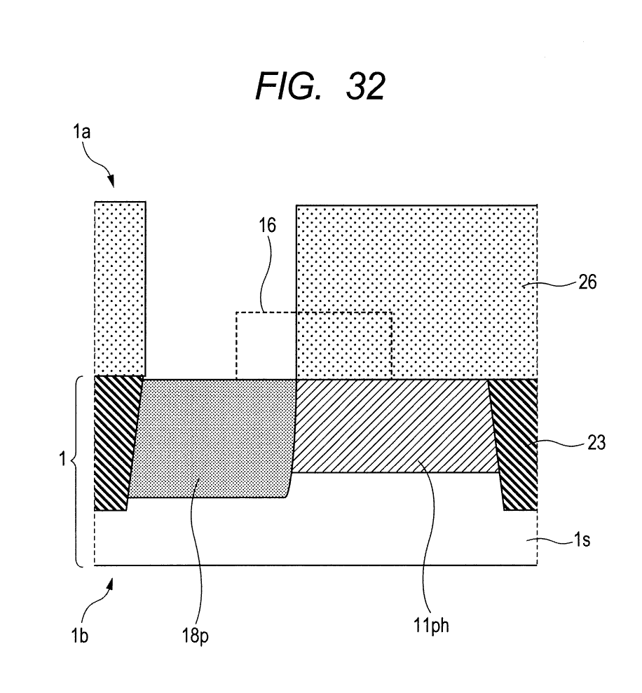

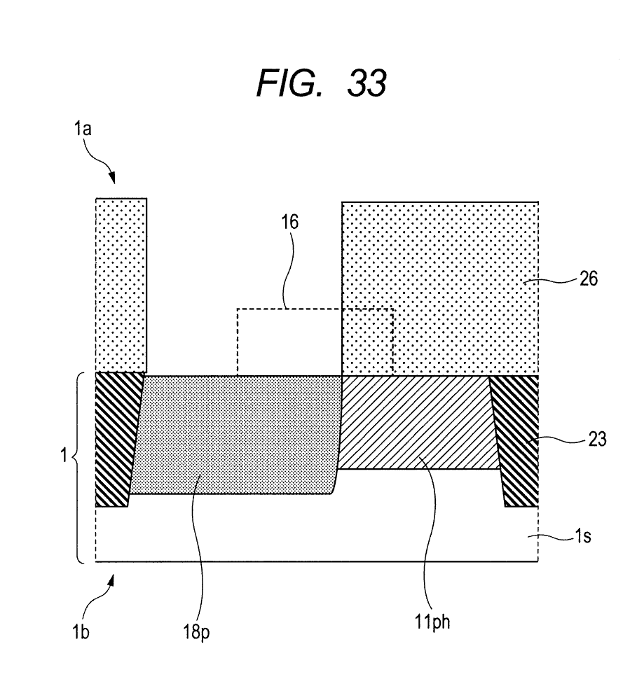

FIG. 31 is an enlarged sectional view of an n-channel high-breakdown voltage asymmetric MISFET (low Vth) explaining the details of the punch through stopper introduction step (FIG. 17) in the basic process. FIG. 32 is an enlarged sectional view of an n-channel high-breakdown voltage asymmetric MISFET (standard Vth) explaining the details of the punch through stopper introduction step (FIG. 17) in the basic process. FIG. 33 is an enlarged sectional view of an n-channel high-breakdown voltage asymmetric MISFET (high Vth) explaining the details of the punch through stopper introduction step (FIG. 17) in the basic process. Description will be given to the details of the punch through stopper introduction step (FIG. 17) in the basic process (multi-Vth) with reference to these drawings.

Description will be given with an n-channel MISFET portion taken as an example. To individually change the threshold voltage of an asymmetric high-breakdown voltage MISFET as a target, for example, the following measure only has to be taken: at the step in FIG. 17, the width of the opening in the resist film 26 for p-type punch through stopper region introduction is individually changed as illustrated in FIG. 31 to FIG. 33.

8. Summary

Up to this point, concrete description has been given to the invention made by the present inventors based on an embodiment. However, the invention is not limited to this embodiment and can be variously modified without departing from the subject matter thereof, needless to add.

An example will be taken. The above concrete description of the embodiment has paid attention mainly to ESD circuit, such as power supply circuit and output circuit, and the like. However, the invention laid open in this specification is not limited to this and is also applicable to signal processing circuits, such as input circuits, I/O circuits, and level shift circuits, and the like, needless to add.

What is claimed is:

1. A semiconductor integrated circuit device comprising:
(a) a semiconductor chip having a first main surface;
(b) a CMIS logic gate provided in a core logic circuit portion over the first main surface of the semiconductor chip;
(c) a first n-channel MISFET comprising the CMIS logic gate;
(d) a first p-channel MISFET comprising the CMIS logic gate;
(e) a CMIS buffer provided in a signal output buffer circuit portion over the first main surface of the semiconductor chip;
(f) a second n-channel MISFET comprising the CMIS buffer and higher in operating voltage than the first n-channel MISFET;
(g) a second p-channel MISFET comprising the CMIS buffer and higher in operating voltage than the first p-channel MISFET;
(h) a CMIS inverter provided in an ESD protection circuit portion over the first main surface of the semiconductor chip;
(i) a third n-channel MISFET comprising the CMIS inverter and higher in operating voltage than the first n-channel MISFET; and
(j) a third p-channel MISFET comprising the CMIS inverter and higher in operating voltage than the first p-channel MISFET,
wherein each of the third n-channel MISFET and the third p-channel MISFET has a source/drain asymmetric structure and includes a halo region only on the source side.

2. The semiconductor integrated circuit device according to claim 1,
wherein each of the third n-channel MISFET and the third p-channel MISFET further includes:
(x1) a high-concentration drain region; and
(x2) a drain extension region deeper than the high-concentration drain region and extended from the drain side to below a gate electrode.

3. The semiconductor integrated circuit device according to claim 2,
wherein the film thickness of the gate insulating film of the third n-channel MISFET and the film thickness of the gate insulating film of the third p-channel MISFET are respectively larger than the film thickness of the gate insulating film of the first n-channel MISFET and the film thickness of the gate insulating film of the first p-channel MISFET.

4. The semiconductor integrated circuit device according to claim 3,
wherein each of the second n-channel MISFET and the second p-channel MISFET has a source/drain asymmetric structure and includes a halo region only on the source side.

5. The semiconductor integrated circuit device according to claim 4,
wherein the threshold voltage of the third n-channel MISFET and the threshold voltage of the third p-channel MISFET are respectively lower than the threshold voltage of the second n-channel MISFET and the threshold voltage of the second p-channel MISFET.

6. The semiconductor integrated circuit device according to claim 5,
wherein each of the third n-channel MISFET and the third p-channel MISFET further includes:
(x1) a punch through stopper region provided on the source side and deeper than the halo region.

7. A semiconductor integrated circuit device comprising:
(a) a semiconductor chip having a first main surface; and
(b) an n-channel MISFET provided in the first main surface of the semiconductor chip and having a source/drain asymmetric structure,
wherein the n-channel MISFET includes:
(b1) an n-type high-concentration source region and an n-type high-concentration drain region formed in the first main surface of the semiconductor chip so that a gate electrode is sandwiched therebetween;
(b2) an n-type source extension region provided at an end of the n-type high-concentration source region on the gate electrode side; and
(b3) a p-type halo region so provided as to surround the n-type source extension region and deeper than the n-type source extension region.

8. The semiconductor integrated circuit device according to claim 7,
wherein the n-channel MISFET further includes:
(b4) an n-type drain extension region deeper than the high-concentration drain region and extended from the drain side to below a gate electrode.

9. The semiconductor integrated circuit device according to claim 8,
wherein the n-channel MISFET further includes:
(b5) a p-type punch through stopper region provided on the source side and deeper than the p-type halo region.

10. A manufacturing method for a semiconductor integrated circuit device comprising:
(a) a semiconductor chip having a first main surface; and
(b) a source/drain asymmetric n-channel MISFET provided in the first main surface of the semiconductor chip,
the source/drain asymmetric n-channel MISFET including:
(b1) a first n-type high-concentration source region and a first n-type high-concentration drain region formed in the first main surface of the semiconductor chip so that a first gate electrode is sandwiched therebetween;
(b2) a first n-type source extension region provided at an end of the first n-type high-concentration source region on the gate electrode side;
(b3) a p-type halo region so provided as to surround the first n-type source extension region and deeper than the first n-type source extension region; and
(b4) a p-type punch through stopper region provided on the source side and deeper than the p-type halo region,
the manufacturing method for the semiconductor integrated circuit device comprising the step of:
(x) introducing the p-type punch through stopper region and the p-type halo region using an identical ion implantation mask.

11. The manufacturing method for the semiconductor integrated circuit device according to claim 10,
wherein the source/drain asymmetric n-channel MISFET further includes:
(b5) a first n-type drain extension region deeper than the first high-concentration drain region and extended from the drain side to below a first gate electrode.

12. The manufacturing method for the semiconductor integrated circuit device according to claim 11,
the semiconductor integrated circuit device further comprising:
(c) a source/drain symmetric n-channel MISFET provided in the first main surface of the semiconductor chip,
the source/drain symmetric n-channel MISFET including:
(c1) a second n-type high-concentration source region and a second n-type high-concentration drain region formed in the first main surface of the semiconductor chip so that a second gate electrode is sandwiched therebetween;
(c2) a second n-type drain extension region deeper than the second high-concentration drain region; and
(c3) a second n-type source extension region deeper than the second high-concentration source region,
the manufacturing method for the semiconductor integrated circuit device comprising the step of:
(y) introducing the first n-type drain extension region and the second n-type source extension region using an identical ion implantation mask.
